(19) United States
(12) Patent Application Publication
(10) Pub. No.: US 2024/0030919 A1
(43) Pub. Date: Jan. 25, 2024

(54) VOLTAGE SUPPLY SELECTION CIRCUIT AND METHODS FOR OPERATING THE SAME

(71) Applicant: Taiwan Semiconductor Manufacturing Company, Ltd., Hsinchu (TW)

(72) Inventors: Chia-Chen Kuo, Hsinchu City (TW); Yangsyu Lin, New Taipei City (TW); Takaaki Nakazato, Hsinchu City (TW); Yu-Hao Hsu, Tainan City (TW); Hung-Jen Liao, Hsinchu City (TW); Jonathan Tsung-Yung Chang, Hsinchu City (TW)

(73) Assignee: Taiwan Semiconductor Manufacturing Company, Ltd., Hsinchu (TW)

(21) Appl. No.: 18/169,594

(22) Filed: Feb. 15, 2023

Related U.S. Application Data
(60) Provisional application No. 63/390,847, filed on Jul. 20, 2022.
(60) Provisional application No. 63/419,961, filed on Oct. 27, 2022.

(51) Int. Cl. H03K 19/0185; H03K 17/693; H03K 19/00

(52) U.S. Cl. CPC H03K 19/018521; H03K 17/693; H03K 19/0027

(57) ABSTRACT

A circuit includes a control circuit configured to receive a selection signal transitioning within a first voltage domain; and generate, based on the selection signal, a first control signal transitioning within a second voltage domain different from the first voltage domain. The circuit further includes a switch circuit operatively coupled to the control circuit and comprising a first header transistor coupled to a first voltage supply transitioning within the second voltage domain, and gated by the first control signal; and a second header transistor coupled to a second voltage supply transitioning within the first voltage domain, and gated by a second control signal that is logically inverse to the first control signal. The first header transistor and the second header transistor are complementarily turned on so as to provide an output voltage equal to either the first voltage supply or the second voltage supply.

### CROSS-REFERENCE TO RELATED APPLICATION

This application claims priority to and the benefit of U.S. Provisional Patent App. No. 63/390,847, filed Jul. 20, 2022, and U.S. Provisional Patent App. No. 63/419,961, filed Oct. 27, 2022, both of which are incorporated herein by reference in their entireties for all purposes.

### BACKGROUND

Voltage scaling is a power management technique used in integrated circuit (IC) design, where a voltage supply can be increased or decreased. For example, in a processor with multiple functional units, a power supply voltage for idle units may be set to a voltage level less than that for active units. As a result, power consumption of the processor can be reduced while increasing performance for active units.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a system including a voltage supply selection circuit and a circuit powered by the voltage supply selection circuit, in accordance with some embodiments.

FIG. 2 illustrates a first implementation of the voltage supply selection circuit of FIG. 1, in accordance with some embodiments.

FIG. 3 illustrates a schematic diagram of the first implementation of the voltage supply selection circuit shown in FIG. 2, in accordance with some embodiments.

FIG. 4 illustrates waveforms of multiple signals presented by the schematic diagram of FIG. 3, in accordance with some embodiments.

FIG. 5 illustrates another schematic diagram of the first implementation of the voltage supply selection circuit shown in FIG. 2, in accordance with some embodiments.

FIG. 6 illustrates waveforms of multiple signals presented by the schematic diagram of FIG. 5, in accordance with some embodiments.

FIG. 7 illustrates yet another schematic diagram of the first implementation of the voltage supply selection circuit shown in FIG. 2, in accordance with some embodiments.

FIGS. 8 and 9 respectively illustrate waveforms of multiple signals presented by the schematic diagram of FIG. 7, in accordance with some embodiments.

FIG. 10 illustrates yet another schematic diagram of the first implementation of the voltage supply selection circuit shown in FIG. 2, in accordance with some embodiments.

FIGS. 11 and 12 respectively illustrate waveforms of multiple signals presented by the schematic diagram of FIG. 10, in accordance with some embodiments.

FIG. 13 illustrates an example layout for fabricating header transistors of the first implementation of the voltage supply selection circuit shown in FIG. 2, in accordance with some embodiments.

FIG. 14 illustrates an alternative schematic diagram of the switch circuit of the first implementation of the voltage supply selection circuit shown in FIG. 2, in accordance with some embodiments.

FIG. 15 illustrates another alternative schematic diagram of the switch circuit of the first implementation of the voltage supply selection circuit shown in FIG. 2, in accordance with some embodiments.

FIG. 16 illustrates a second implementation of the voltage supply selection circuit of FIG. 1, in accordance with some embodiments.

FIG. 17 illustrates a schematic diagram of the second implementation of the voltage supply selection circuit shown in FIG. 16, in accordance with some embodiments.

FIG. 18 illustrates waveforms of multiple signals presented by the schematic diagram of FIG. 17, in accordance with some embodiments.

FIG. 19 illustrates another schematic diagram of the second implementation of the voltage supply selection circuit shown in FIG. 16, in accordance with some embodiments.

FIGS. 20 and 21 respectively illustrate waveforms of multiple signals presented by the schematic diagram of FIG. 19, in accordance with some embodiments.

FIG. 22 illustrates yet another schematic diagram of the second implementation of the voltage supply selection circuit shown in FIG. 16, in accordance with some embodiments.

FIGS. 23 and 24 respectively illustrate waveforms of multiple signals presented by the schematic diagram of FIG. 22, in accordance with some embodiments.

FIG. 25 illustrates a schematic diagram of a maximum voltage selection circuit included in the second implementation of the voltage supply selection circuit shown in FIG. 16, in accordance with some embodiments.

FIG. 26 illustrates another schematic diagram of a maximum voltage selection circuit included in the second implementation of the voltage supply selection circuit shown in FIG. 16, in accordance with some embodiments.

FIG. 27 illustrates a flow chart of an example method for operating the voltage supply selection circuit of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides various embodiments of a voltage supply selection circuit that can provide one of a first voltage supply or a second voltage supply depending on a selection signal. The first voltage supply and second voltage supply may be configured in a first voltage domain and second voltage domain, respectively. In some embodiments, the voltage supply selection circuit can include at least a first header transistor and a second header transistor coupled to the first voltage supply and the second voltage supply, respectively. The first and second header transistors can be complementarily controlled (e.g., turned on) by first and second control signals that are generated based on the selection signal, respectively. According to various embodiments, the first and second control signals may be configured in a same one of the first or second voltage domain, and logically inverse to each other. As such, when one of the two paths, respectively coupled to the first and second voltage supplies, is conducted, the other path can be fully cut off. Existing voltage supply selection circuits typically rely on similar header transistors respectively coupled to different voltage supplies. By complementarily turning on one of the header transistors, one of the voltage supplies can be provided. However, the header transistors of the existing voltage supply selection circuit are controlled by signals in different voltage domains, which can induce leakage conducting through one of the header transistors when a lower one of the voltage supplies is selected (sometimes referred to as cross-domain leakage). As the header transistors of the disclosed voltage supply selection circuit are controlled by signals in the same voltage domain, leakage incurred (e.g., along the unselected path or through one of the header transistors) due to cross of the voltage domains can be almost entirely eliminated. Therefore, the voltage supply selection circuit, as disclosed herein, can further reduce power consumption over the existing voltage supply selection circuits, which allows itself to be more efficiently integrated into other circuits.

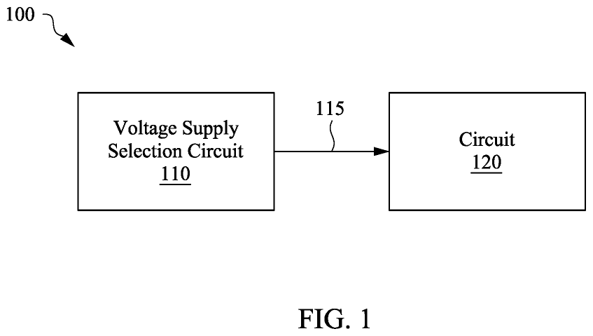

FIG. 1 is an illustration of a system 100 for selecting a voltage supply, according to some embodiments of the present disclosure. The system 100 includes a voltage supply selection circuit 110 and a circuit 120. In some embodiments, the circuit 120 can be a processor device (e.g., a central processing unit (CPU) device and a graphics processing unit (GPU) device), a memory device (e.g., a dynamic random access memory (DRAM) device and a static random access memory (SRAM) device), an input/output interface device (e.g., a peripheral component interface (PCI) device and a serializer/deserializer (SerDes) device), or any other type of device that can implement voltage scaling techniques.

In some embodiments, the voltage supply selection circuit 110 provides a voltage supply 115 to the circuit 120. The voltage supply 115 can be a power supply voltage, such as a power supply voltage associated with logic devices (“V_{DD}”) or a power supply voltage associated with memory device operations (“V_{DDM}”), according to some embodiments of the present disclosure. The V_{DD} voltage level can be, for example, within a range of about 0.4 V to about 5.0 V. Other values are within the spirit and scope of the present disclosure. The V_{DDM} voltage level can be, for example, within a range of about 0.6 V to about 2.0 V. Other values are within the spirit and scope of the present disclosure. In some embodiments, the V_{DD} voltage level can be lower than the V_{DDM} voltage level during a normal mode of operation for the system 100 (e.g., when the system 100 is not in a high performance mode of operation). When the system 100 is in a high performance mode of operation, the V_{DD} voltage level can transition to a higher voltage level than that of the V_{DDM} voltage level. The V_{DDM} voltage level can remain substantially the same during the normal and high performance modes of operation for the system 100, according to some embodiments of the present disclosure. Though the description below refers to V_{DD} and V_{DDM} as voltage supplies for example purposes, other voltage supplies can be used with the embodiments described herein. These other voltage supplies are within the spirit and scope of the present disclosure.

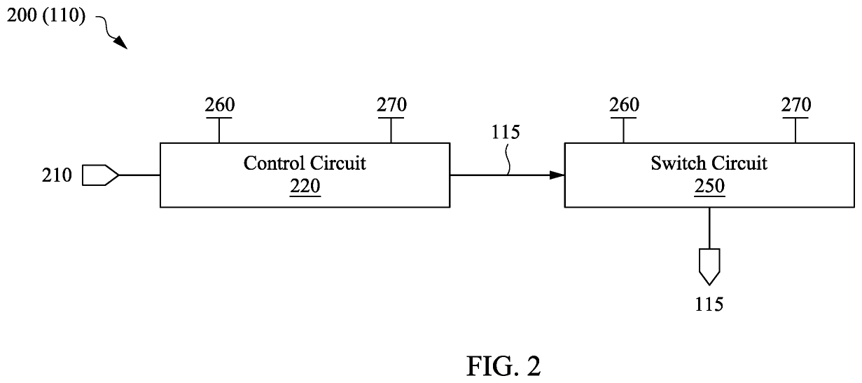

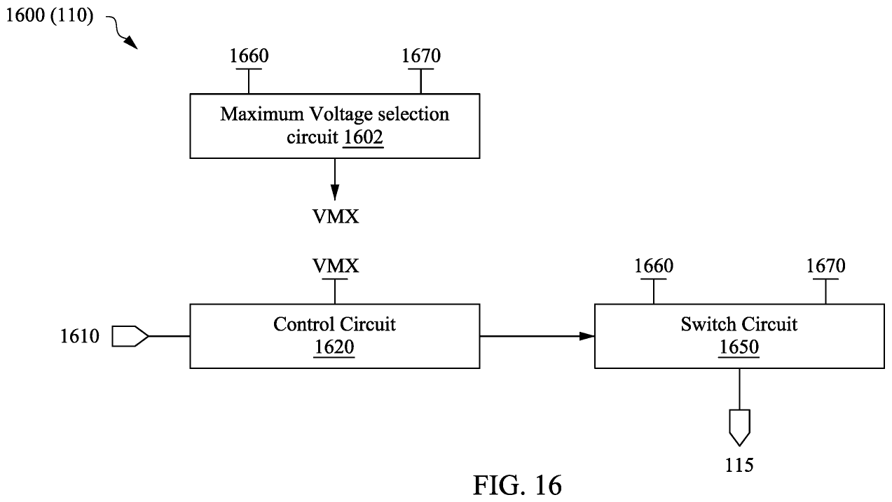

The voltage supply selection circuit 110 can provide multiple voltage levels for the voltage supply 115—e.g., V_{DD} and V_{DDM}—to the circuit 120 based on a selection signal (not shown in FIG. 1; described below with regard to selection signal 210 of FIG. 2 and selection signal 1610 of FIG. 16). In some embodiments, the voltage supply selection circuit 110 provides a voltage scaling functionality to the circuit 120, in which the circuit 120 can receive one of two voltage supplies (e.g., V_{DD} or V_{DDM}) to facilitate in a high performance mode of operation and to manage power consumption in the circuit 120.

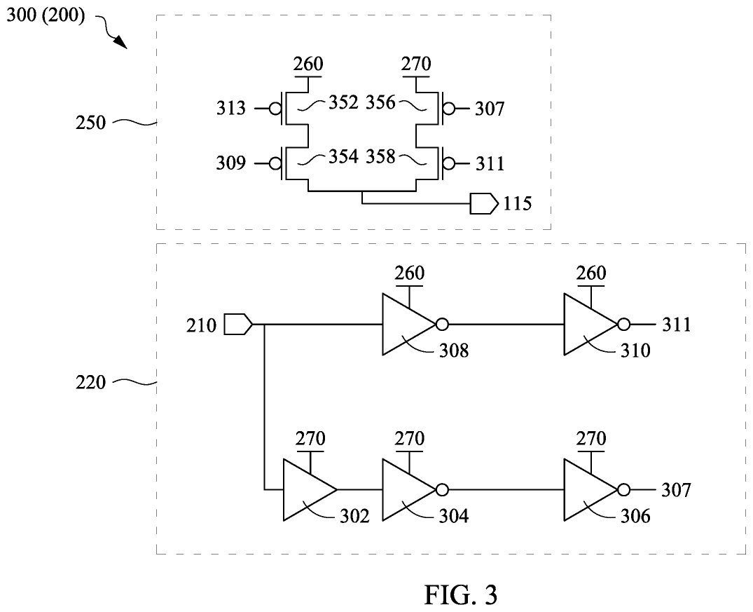

For example, when the circuit 120 requires a higher voltage supply to facilitate a high performance mode of operation (e.g., at a higher frequency to execute circuit operations faster), the voltage supply selection circuit 110 can provide a higher voltage level to the voltage supply 115 (e.g., V_{DD} transitioning from a lower to higher voltage level; described below with regard to second voltage supply 270 of FIGS. 2-3) to the circuit 120. When the circuit 120 is not in a high performance mode of operation and reduces power consumption, the voltage supply selection circuit 110 can provide a lower voltage level to the voltage supply 115 (e.g., V_{DDM}; described below with regard to first voltage supply 260 of FIGS. 2-3) to the circuit 120. In some embodiments, the higher and lower voltage levels of the voltage supply 115 (e.g., V_{DD} and V_{DDM}) can be determined based on the selection signal (e.g., selection signal 210 of FIG. 2 or 3).

FIG. 2 is an example illustration 200 of the voltage supply selection circuit 110 (hereinafter “voltage supply selection circuit 200”), according to some embodiments of the present disclosure. As shown, the voltage supply selection circuit 200 includes a switch control (sometimes referred to as a control circuit) 220 and a voltage supply switch (sometimes referred to as a switch circuit) 250. The voltage supply selection circuit 200 receives (or is electrically coupled to) a selection signal 210 as an input. In some embodiments, the selection signal 210 can be provided to voltage supply selection circuit 200 by the circuit 120 (FIG. 1) or by another circuit not shown in the system 100 (FIG. 1). Based on the selection signal 210, the voltage supply selection circuit 200 can output either a first voltage supply 260 or a second voltage supply 270 at the voltage supply 115.

In some embodiments, the first voltage supply 260 can be V_{DDM} and second voltage supply 270 can be V_{DD}. The first voltage supply 260 (V_{DDM}) may be configured in a first voltage domain (sometimes referred to as V_{DDM} domain), and the second voltage supply 270 (V_{DD}) may be configured in a second voltage domain (sometimes referred to as V_{DD} domain). Further, the first voltage supply 260 (within the V_{DDM} domain) may be fixed at a constant voltage level over time, while the second voltage supply 270 (within the V_{DD} domain) may transition from a lower voltage level to a higher voltage level over time, according to some implementation of the present disclosure.

In brief overview, the control circuit 220 can receive (or be electrically coupled to) the selection signal 210 as an input. The control circuit 220 can further include a first part and a second part receiving the first voltage supply 260 (V_{DDM}) and the second voltage supply 270 (V_{DD}) as their power supply voltages, respectively. Alternatively stated, the first part and the second part can operate in the first voltage domain (V_{DDM} domain) and the second voltage domain (V_{DD} domain), respectively. Based on the selection signal 210, the first part and second part of the control circuit 220 can provide a number of control signals to the switch circuit 250, which is electrically coupled to both of the first voltage supply 260 and second voltage supply 270. The switch circuit 250 can then output the voltage supply 115 equal to the first voltage supply 260 or second voltage supply 270 based on the control signals.

FIG. 3 illustrates a schematic diagram of an example circuit 300 implemented as the voltage supply selection circuit 200 shown in FIG. 2. As shown in FIG. 3, the control circuit 220 includes a first part having inverters 308 and 310, and a second part having level shifter 302 and inverters 304 and 306. The first part may operate in the first voltage domain (V_{DDM} domain), while the second part may operate in the second voltage domain (V_{DD} domain). In other words, the inverters 308-310 can operate with the first voltage supply 260 (V_{DDM}), and the level shifter 302 and inverters 304-406 can operate with the second voltage supply 270 (V_{DD}). The switch circuit 250 includes a number of header transistors 352, 354, 356, and 358. Each of the header transistors 352 to 358 is implemented as a p-type metal-oxide-semiconductor (PMOS) field-effect-transistor. However, it should be understood that the header transistors 352 to 358 can each be implemented as any of various other types of transistors, while remaining within the scope of the present disclosure.

According to various embodiments, with the circuit 300 shown in FIG. 3, the selection signal 210 may be configured in the first voltage domain (V_{DDM} domain). As such, the inverter 308 (powered by the first voltage supply 260, V_{DDM}) can logically invert the selection signal 210 and provide it to the inverter 310 (powered by the first voltage supply 260, V_{DDM}) so as to provide a control signal 311 in the V_{DDM} domain. The level shifter 302 (powered by the second voltage supply 270, V_{DD}) can shift the selection signal 210 from the first voltage domain (V_{DDM} domain) to the second voltage domain (V_{DD} domain), and provide it to the inverter 304 (powered by the second supply voltage 270, V_{DD}). The inverter 304 can logically invert the shifted selection signal and provide it to the inverter 306 (powered by the second voltage supply 270, V_{DD}) so as to provide a control signal 307 in the V_{DD} domain.

The control signal 307 is received by a gate of the header transistor 356, and the control signal 311 is received by a gate of the header transistor 358. The header transistors 356 and 358, connected to each other in series, are further coupled between the second voltage supply 270 (V_{DD}) and an output node of the voltage supply selection circuit 200 presenting the voltage supply 115. For example, a source of the header transistor 356 is connected to the second voltage supply 270 (V_{DD}) a drain of the header transistor 356 is connected to a source of the header transistor 358, and a drain of the header transistor 358 is connected to the output node (voltage supply 115). Similarly, the header transistors 352 and 354, connected to each other in series, are further coupled between the first voltage supply 260 (V_{DDM}) and the output node (voltage supply 115). A control signal 313, that is logically inverted to the control signal 311, is received by a gate of the header transistor 352, and a control signal 309, that is logically inverted to the control signal 307, is received by a gate of the header transistor 354.

In some embodiments, the header transistors 356 and 358 may form a second conduction path configured to selectively couple the second voltage supply 270 (V_{DD}) to the voltage supply 115, and the header transistors 352 and 354 may form a first conduction path configured to selectively couple the first voltage supply 260 (V_{DDM}) to the voltage supply 115. The first and second conduction paths may be complementarily conducted or otherwise selected based on the control signals 307 to 313, in which the control signals 307 and 309 (and the control signals 311 and 313) are logically inverted to each other. For example when the selection signal is at logic high, the control signals 307 and 311, even in respectively different voltage domains, can be both pulled to logic high, which turns off both of the header transistors 356 and 358, while the control signals 309 and 313 (even in respectively different voltage domains) can be both pulled to logic low, which turns on both of the header transistors 352 and 354. As such, the first conduction path is conducted so as to output the voltage supply 115 as the first voltage supply 260 (V_{DDM}), while the second conduction path can be almost entirely shut off. Table I below shows a summary of logic states of the selection signal 210, control signals 307 to 313, and the voltage supply 115.

TABLE I

| 210 | 313 | 309 | 311 | 307 | 115 |
|---|---|---|---|---|---|
| 0 | 1 | 1 | 0 | 0 | V_{DD} |
| 1 | 0 | 0 | 1 | 1 | V_{DDM} |

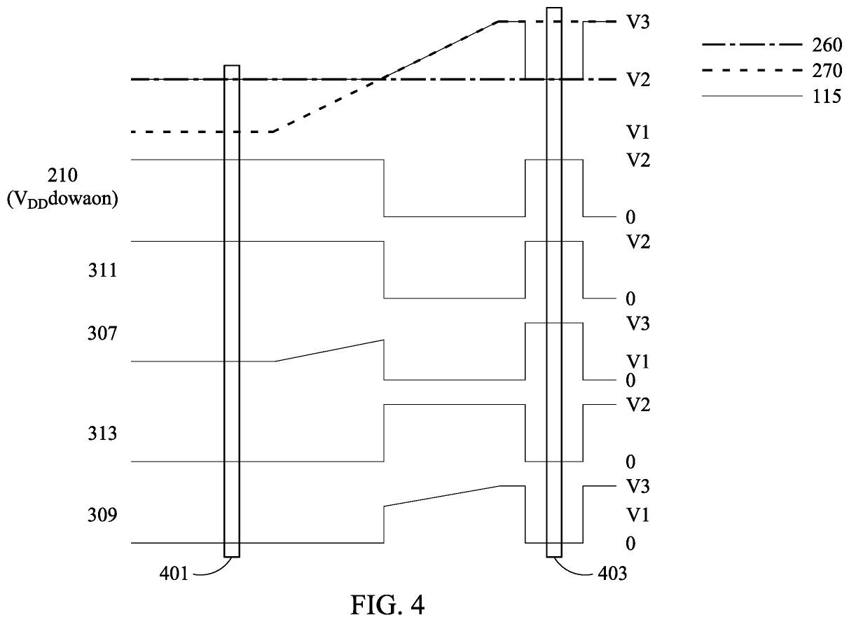

FIG. 4 illustrates analog waveforms of the selection signal 210, the control signals 307 to 313, the voltage supplies 260-270, and the voltage supply 115 presented by the circuit 300 of FIG. 3 over time, according to some embodiments of the present disclosure. The selection signal 210 is configured in the first voltage domain (V_{DDM}) for the example circuit 300 shown in FIG. 3. For example, the selection signal 210 may transition between voltage levels: 0 volts and V2 volts, which correspond to logic low and logic high in the V_{DDM} domain, respectively. As such, the control signals 311 and 313 are also configured in the first voltage domain (V_{DDM}), while the control signals 307 and 309 are configured in the second voltage domain (V_{DD}). For example, the control signals 309 and 309 may transition between voltage levels: 0 volts and V3 volts, which correspond to logic low and logic high in the V_{DD} domain, respectively. Further, in some implementation, the first voltage supply 260 may be fixed at V2 volts, with the second voltage supply 270 varying from V1 volts to the V3 volts, in which V1 is less than V2 and V2 is less than V3.

During an example time period 401 indicated in FIG. 4, the selection signal 210 is provided at logic high (i.e., V2 volts). Upon receiving the selection signal 210, the level shifter 302 can shift it to the V_{DD} domain, i.e., V3 volts, and output to the inverters 304 and 306, which causes the control signal 307 at logic high, i.e., V3 volts. On the other hand (without being shifted), the inverter 310 can output the control signal 311 also at logic high, i.e., V2 volts. Accordingly, the header transistors 356 and 358, respectively gated by the control signals 307 and 311, can be turned off, while the header transistors 352 and 354, respectively gated by the control signals 313 and 309, can be turned on. The first supply voltage 260 (fixed at V2 volts) is thus coupled to the voltage supply 115. In addition, each of the header transistors 356 and 358 can be entirely shut off in such a case (the first voltage supply 260>the second voltage supply 270), with its voltage drop across the source and gate being equal to 0 volts. For example, the source and gate of the header transistor 358 are both equal to V2 volts.

During another example time period 403 indicated in FIG. 4, similarly, the header transistors 356 and 358 are turned off, while the header transistors 352 and 354 are turned on. Thus, the first supply voltage 260 (fixed at V2 volts) is coupled to the voltage supply 115. However, in such a case, the first voltage supply 260 is instead lower than the second voltage supply 270. Even so, each of the header transistors 356 and 358 can still be entirely shut off, with its voltage drop across the source and gate being equal to 0 volts. For example, the source and gate of the header transistor 356 are both equal to V3 volts.

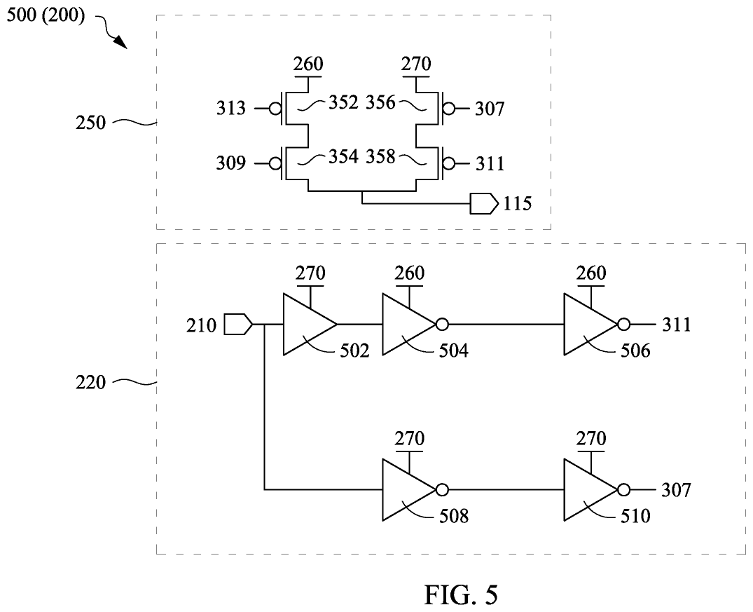

FIG. 5 illustrates a schematic diagram of another example circuit 500 implemented as the voltage supply selection circuit 200 shown in FIG. 2. The circuit 500 of FIG. 5 is substantially similar to the circuit 300 of FIG. 3, except that the selection signal 210 received by the circuit 500 is configured in the second voltage domain (V_{DD} domain). For example, the circuit 500 and circuit 300 have their respective switch circuits 250 configured by the same circuit-level representation. Thus, the following description of the circuit 500 will be focused on the difference.

As shown, the control circuit 220 in the circuit 500 includes a first part having level shifter 502 and inverters 504 and 506, and a second part having inverters 508 and 510. The first part may operate in the first voltage domain (V_{DDM} domain), while the second part may operate in the second voltage domain (V_{DD} domain). In other others, the level shifter 502 and inverters 504-506 can operate with the first voltage supply 260 (V_{DDM}), and the inverters 508-510 can operate with the second voltage supply 270 (V_{DD}). Further, the inverter 508 (powered by the second voltage supply 270, V_{DD}) can logically invert the selection signal 210 and provide it to the inverter 510 (powered by the second voltage supply 270, V_{DD}) so as to provide the control signal 307 in the V_{DD} domain. The level shifter 502 (powered by the first voltage supply 260, V_{DDM}) can shift the selection signal 210 from the second voltage domain (V_{DD} domain) to the first voltage domain (V_{DDM} domain), and provide it to the inverter 504 (powered by the first supply voltage 260, V_{DDM}). The inverter 504 can logically invert the shifted selection signal and provide it to the inverter 506 (powered by the first voltage supply 260, V_{DDM}) so as to provide the control signal 311 in the V_{DDM} domain.

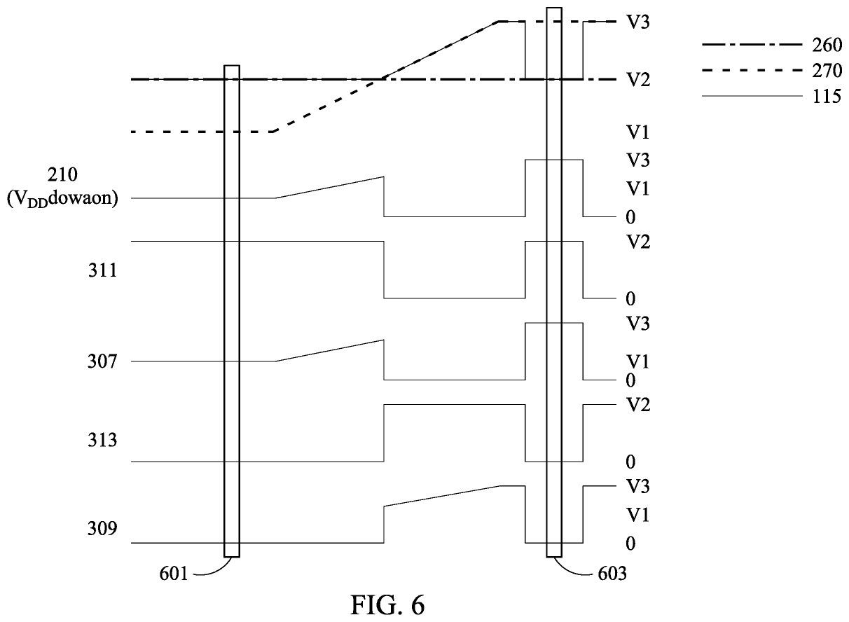

FIG. 6 illustrates analog waveforms of the selection signal 210, the control signals 307 to 313, the voltage supplies 260-270, and the voltage supply 115 presented by the circuit 500 of FIG. 5 over time, according to some embodiments of the present disclosure. The analog waveforms of FIG. 6 are substantially similar to those shown in FIG. 4, except that the selection signal 210 is configured in the second voltage domain (V_{DD}) for the example circuit 500 shown in FIG. 5. As such, the selection signal 210 may transition between voltage levels: 0 volts and V3 volts, which correspond to logic low and logic high in the V_{DD} domain, respectively. Similarly, during any time period 601 or 603 indicated in FIG. 6 where the first supply voltage 260 (V2 volts) is coupled to the voltage supply 115, the unselected conduction path (e.g., through the header transistors 356 and 358) can be completely cut off, i.e., no leakage.

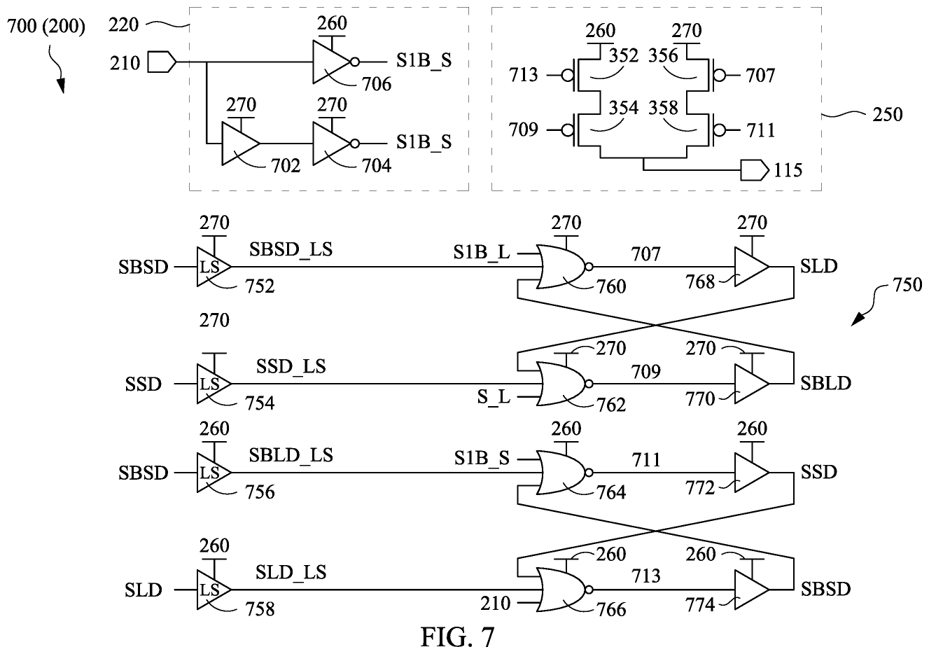

FIG. 7 illustrates a schematic diagram of yet another example circuit 700 implemented as the voltage supply selection circuit 200 shown in FIG. 2. The circuit 700 and circuit 300 (FIG. 3) have their respective switch circuits 250 configured by the same circuit-level representation. The circuit 700 further includes a timing control circuit 750 configured to assure that the header transistors 352 to 356 can remain on during switching between the first voltage supply 260 (V_{DDM}) and the second voltage supply 270 (V_{DD}).

As shown in FIG. 7, the control circuit 220 of the circuit 700 includes a first part having inverter 706 powered by the first voltage domain 260 (V_{DDM}), and a second part having level shifter 702 and inverter 704 powered by the second voltage domain 270 (V_{DD}). According to various embodiments, with the circuit 700 shown in FIG. 7, the selection signal 210 may be configured in the first voltage domain (V_{DDM} domain). As such, the inverter 706 (powered by the first voltage supply 260, V_{DDM}) can logically invert the selection signal 210 to provide signal, SIB S, in the V_{DDM} domain. The level shifter 702 (powered by the second voltage supply 270, V_{DD}) can shift the selection signal 210 from the first voltage domain (V_{DDM} domain) to the second voltage domain (V_{DD} domain) as signal, S_L, and provide it to the inverter 704 (powered by the second supply voltage 270, V_{DD}). The inverter 704 can logically invert the shifted selection signal (S_L) to provide signal, S1B_L, in the V_{DD} domain. The signals S1B_S and S1B_L can provided as input signals to the timing control circuit 750, as will be discussed below.

The timing control circuit 750 includes level shifters 752, 754, 756, and 758, NOR gates 760, 762, 764, and 766, and delay circuits 768, 770, 772, and 774. In some embodiments, the delay circuits 768 to 774 can each include a respective number of inverters serially connected to one another. The level shifters 752-754, NOR gates 760-762, and delay circuits 768-770 may operate with the second voltage supply 270 (V_{DD}); and the level shifters 756-758, NOR gates 764-766, and delay circuits 772-774 may operate with the first voltage supply 260 (V_{DDM}). The level shifters 752 and 754 can shift delayed signals SBSD and SSD from the first voltage domain (V_{DDM} domain) to the second voltage domain (V_{DD} domain) and output them as signals SBSB_LS and SSD_LS, respectively; and the level shifters 756 and 758 can shift delayed signals SBLD and SLD from the second voltage domain (V_{DD} domain) to the first voltage domain (V_{DDM} domain) and output then as signals SBLD_LS and SLD_LS, respectively. The delayed signals SLD, SBLD, SSD, and SBSD are provided by the delay circuits 768, 770, 772, and 774, respectively.

Further, the NOR gates 760 and 762 form a first NOR-type SR latch operating with the second voltage supply 270 and having its outputs coupled to the delayed circuits 768-770; and the NOR gates 764 and 766 form a second NOR-type SR latch operating with the first voltage supply 260 and having its outputs coupled to the delayed circuits 772-774. For example in FIG. 7, the NOR gate 760 receives the signals S1B_L, SBSD LS, and SBLD as inputs to provide control signal 707; the NOR gate 762 receives the signals S_L, SSD_LS, and SLD as inputs to provide control signal 709; the NOR gate 764 receives the signals SIB S, SBLD_LS, and SBSD as inputs to provide control signal 711; and the NOR gate 766 receives the signals 210, SLD_LS, and SSD as inputs to provide control signal 713. By combining the NOR-type SR latches with the delayed circuits, the control signals 707 to 713, which gate the header transistors 356, 354, 358, and 352, respectively, can be held at logic low during the switching between the first voltage supply 260 and second voltage supply 270 (i.e., transition of the selection signal 210). Thus, the header transistors 352 to 358 can remain on during the switching, which can advantageously prevent the voltage supply 115 from floating during the transition of the selection signal 210.

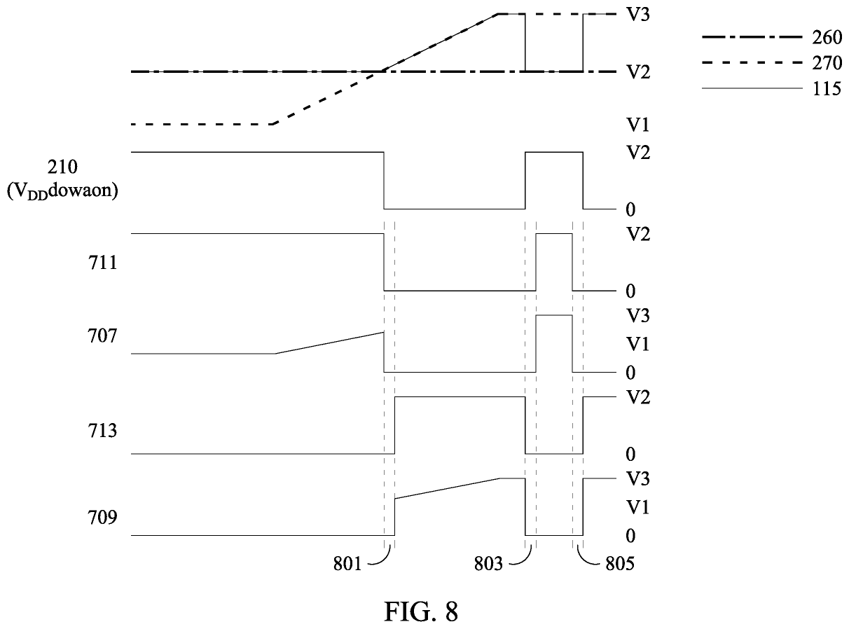

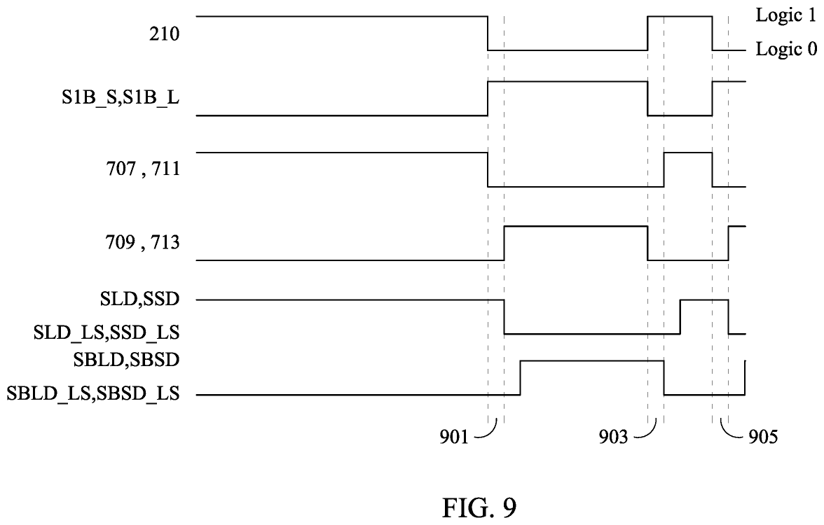

FIG. 8 and FIG. 9 illustrate analog waveforms and logic waveforms presented by the circuit 700 of FIG. 7 over time, respectively. For example, FIG. 8 illustrates analog waveforms of the selection signal 210, the first and second voltage supplies 260-270, the voltage supply 115, and the control signals 709 to 713, respectively; and FIG. 9 illustrates logic waveforms of the selection signal 210, control signals 709 to 713, and signals SIB S, S1B_L, SLD, SSD, SLD_LS, SSD_LS, SBLD, SBSD, SBLD_LS, and SBSD LS, respectively. As shown in FIG. 8, during the transition of selection signal 210, e.g., time periods 801, 803, and 805, each of the control signals 709 to 713 are held at logic low. Thus, the header transistors 352 to 358 can remain on during such periods, thereby preventing the voltage supply 115 from floating. Time periods 901, 903, and 905, as indicted in FIG. 9, can correspond to the time periods 801, 803, and 805, respectively, during which the control signals 709 to 713 remain at logic low.

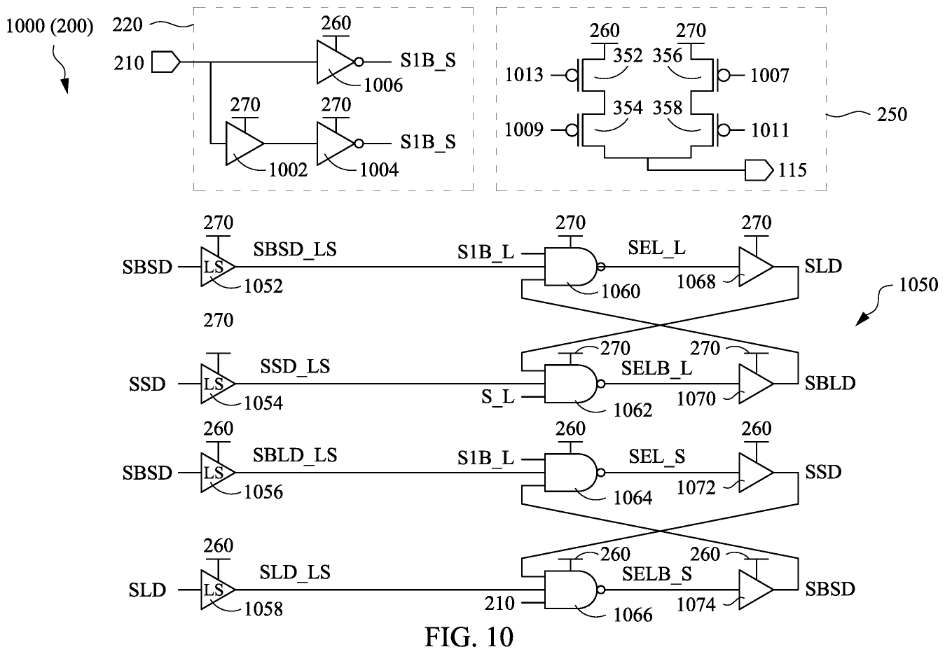

FIG. 10 illustrates a schematic diagram of yet another example circuit 1000 implemented as the voltage supply selection circuit 200 shown in FIG. 2. The circuit 1000 and circuit 300 (FIG. 3) have their respective switch circuits 250 configured by the same circuit-level representation. The circuit 1000 further includes a timing control circuit 1050 configured to assure that the header transistors 352 to 356 can remain off during switching between the first voltage supply 260 (V_{DDM}) and the second voltage supply 270 (V_{DD}).

As shown in FIG. 10, the control circuit 220 of the circuit 1000 includes a first part having inverter 1006 powered by the first voltage domain 260 (V_{DDM}), and a second part having level shifter 1002 and inverter 1004 powered by the second voltage domain 270 (V_{DD}). According to various embodiments, with the circuit 1000 shown in FIG. 10, the selection signal 210 may be configured in the first voltage domain (V_{DDM} domain). As such, the inverter 1006 (powered by the first voltage supply 260, V_{DDM}) can logically invert the selection signal 210 to provide signal, SIB S, in the V_{DDM} domain. The level shifter 1002 (powered by the second voltage supply 270, V_{DD}) can shift the selection signal 210 from the first voltage domain (V_{DDM} domain) to the second voltage domain (V_{DD} domain) as signal, S_L, and provide it to the inverter 1004 (powered by the second supply voltage 270, V_{DD}). The inverter 1004 can logically invert the shifted selection signal (S_L) to provide signal, S1B_L, in the V_{DD} domain. The signals S1B_S and S1B_L can provided as input signals to the timing control circuit 1050, as will be discussed below.

The timing control circuit 1050 includes level shifters 1052, 1054, 1056, and 1058, NAND gates 1060, 1062, 1064, and 1066, and delay circuits 1068, 1070, 1072, and 1074. In some embodiments, the delay circuits 1068 to 1074 can each include a respective number of inverters serially connected to one another. The level shifters 1052-1054, NAND gates 1060-1062, and delay circuits 1068-1070 may operate with the second voltage supply 270 (V_{DD}); and the level shifters 1056-1058, NAND gates 1064-1066, and delay circuits 1072-1074 may operate with the first voltage supply 260 (V_{DDM}). The level shifters 1052 and 1054 can shift delayed signals SBSD and SSD from the first voltage domain (V_{DDM} domain) to the second voltage domain (V_{DD} domain) and output them as signals SBSB_LS and SSD_LS, respectively; and the level shifters 1056 and 1058 can shift delayed signals SBLD and SLD from the second voltage domain (V_{DD} domain) to the first voltage domain (V_{DDM} domain) and output then as signals SBLD_LS and SLD_LS, respectively. The delayed signals SLD, SBLD, SSD, and SBSD are provided by the delay circuits 1068, 1070, 1072, and 1074, respectively.

Further, the NAND gates 1060 and 1062 form a first NAND-type SR latch operating with the second voltage supply 270 and having its outputs coupled to the delayed circuits 1068-1070; and the NAND gates 1064 and 1066 form a second NAND-type SR latch operating with the first voltage supply 260 and having its outputs coupled to the delayed circuits 1072-1074. For example in FIG. 10, the NAND gate 1060 receives the signals S1B_L, SBSD LS, and SBLD as inputs to provide control signal 1007; the NAND gate 1062 receives the signals S_L, SSD_LS, and SLD as inputs to provide control signal 1009; the NAND gate 1064 receives the signals 51B S, SBLD_LS, and SBSD as inputs to provide control signal 1011; and the NAND gate 1066 receives the signals 210, SLD_LS, and SSD as inputs to provide control signal 1013. By combining the NAND-type SR latches with the delayed circuits, the control signals 1007 to 1013, which gate the header transistors 356, 354, 358, and 352, respectively, can be held at logic high during the switching between the first voltage supply 260 and second voltage supply 270 (i.e., transition of the selection signal 210). Thus, the header transistors 352 to 358 can remain off during the switching, which can advantageously prevent the voltage supply 115 from floating during the transition of the selection signal 210.

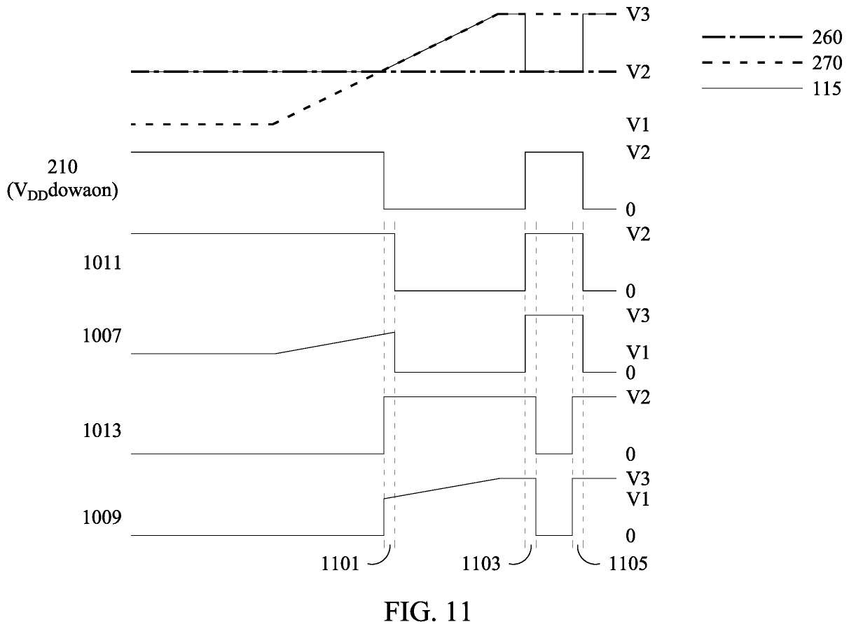

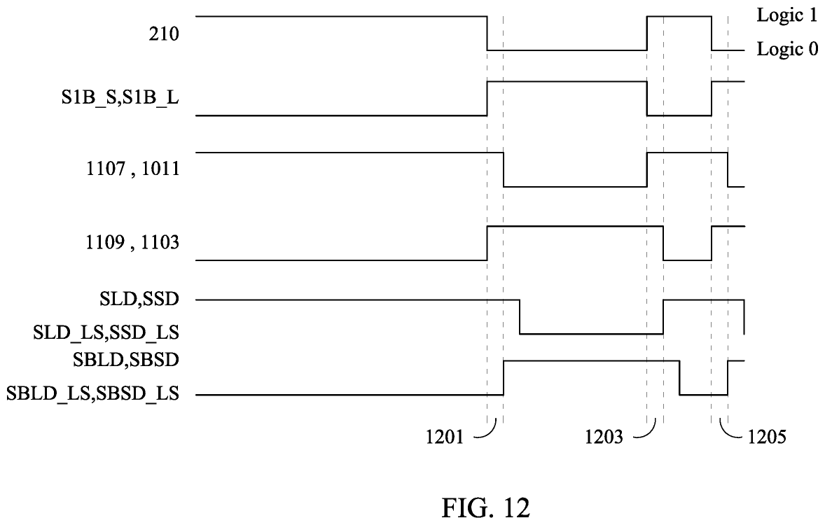

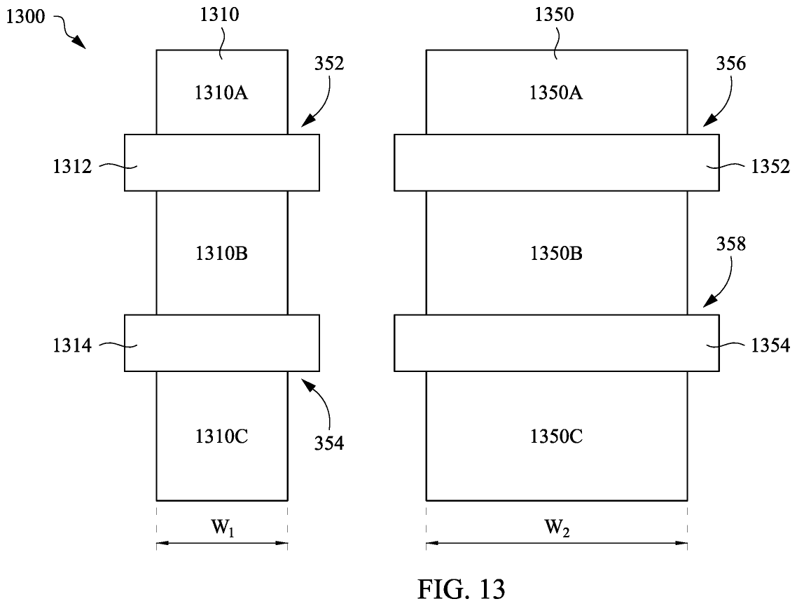

FIG. 11 and FIG. 12 illustrate analog waveforms and logic waveforms presented by the circuit 1000 of FIG. 10 over time, respectively. For example, FIG. 11 illustrates analog waveforms of the selection signal 210, the first and second voltage supplies 260-270, the voltage supply 115, and the control signals 1009 to 1013, respectively; and FIG. 13 illustrates logic waveforms of the selection signal 210, control signals 1009 to 1013, and signals SIB S, S1B_L, SLD, SSD, SLD_LS, SSD_LS, SBLD, SBSD, SBLD_LS, and SBSD LS, respectively. As shown in FIG. 11, during the transition of selection signal 210, e.g., time periods 1101, 1103, and 1105, each of the control signals 1009 to 1013 are held at logic high. Thus, the header transistors 352 to 358 can remain off during such periods, thereby preventing the voltage supply 115 from floating. Time periods 1201, 1203, and 1205, as indicted in FIG. 12, can correspond to the time periods 1101, 1103, and 1105, respectively, during which the control signals 1009 to 1013 remain at logic high.

In some embodiments, the header transistors 352 and 354 coupled to the first voltage supply 260 and the header transistors 356 and 358 coupled to the second voltage supply 270 may be configured in respectively different sizes, which can further reduce leakage and/or optimize IR performance. For example, in some scenarios where the second voltage supply 270 (V_{DD}) is configured to be higher than the first voltage supply 260 (V_{DDM}), the header transistors 356 and 358 can be configured to have a wider channel width than the header transistors 352 and 354 do.

FIG. 13 illustrates an example layout 1300 that can be utilized to fabricate such header transistors 352 to 358. As shown, the layout 1300 includes active regions 1310 and 1350 formed over a substrate. Depending on which transistor structure the header transistors 352 to 358 are formed as, the active regions 1310 and 1350 can be formed in various types of structures. For example, if the header transistors 352 to 358 are each formed as a FinFET, the active regions 1310 and 1350 may each be formed as a fin structure protruding out from the substrate. In another example, if the header transistors 352 to 358 are each formed as a gate-all-around (GAA) FET, the active regions 1310 and 1350 may each be formed as a non-planar structure protruding out from the substrate and having at least two different semiconductor layers alternately disposed on top of one another. The layout 1300 further includes gate regions 1312 and 1314 traversing respective portions of the active region 1310, and gate regions 1352 and 1354 traversing respective portions of the active region 1350. The gate regions 1312 to 1354 can each be utilized to define the gate structure of a transistor.

Accordingly, the gate region 1312, the portion of the active region 1310 overlaid by the gate region 1312, and portions of the active region 1310 (1310A and 1310B) on opposite sides of the gate region 1312 can define the header transistor 352's gate, channel, source, and drain, respectively; the gate region 1314, the portion of the active region 1310 overlaid by the gate region 1314, and portions of the active region 1310 (1310B and 1310C) on opposite sides of the gate region 1314 can define the header transistor 354's gate, channel, source, and drain, respectively; the gate region 1352, the portion of the active region 1350 overlaid by the gate region 1352, and portions of the active region 1350 (1350A and 1350B) on opposite sides of the gate region 1352 can define the header transistor 356's gate, channel, source, and drain, respectively; and the gate region 1354, the portion of the active region 1350 overlaid by the gate region 1354, and portions of the active region 1350 (1350B and 1350C) on opposite sides of the gate region 1354 can define the header transistor 358's gate, channel, source, and drain, respectively.

With such configurations, the portion 1310A (i.e., the source of the header transistor 352) can be electrically coupled to the first voltage supply 260 (V_{DDM}) and the portion 1310C (i.e., the drain of the header transistor 354) can be electrically coupled to the voltage supply 115, with the portion 1310B shared by the header transistors 352 and 354; and the portion 1350A (i.e., the source of the header transistor 356) can be electrically coupled to the second voltage supply 270 (V_{DD}) and the portion 1350C (i.e., the drain of the header transistor 358) can be electrically coupled to the voltage supply 115, with the portion 1350B shared by the header transistors 356 and 358.

As shown, the active region 1310 can have a first width along a lengthwise direction of the gate region 1312/1314 (W₁), and the active region 1350 can have a second width along a lengthwise direction of the gate region 1352/1354 (W₂). In some embodiments, the width W₂ is not necessarily equal to the width W₁. In the example where the second voltage supply 270 (V_{DD}) is configured to be higher than the first voltage supply 260 (V_{DDM}), the width W₂ can be greater than the width W₁. Equivalently, the header transistors 356 and 358 have a wider channel width than the header transistors 352 and 354 do, which allows the header transistors 356 and 358 coupled to the higher voltage supply (e.g., the second voltage supply 270 (V_{DD})) to have even better leakage control.

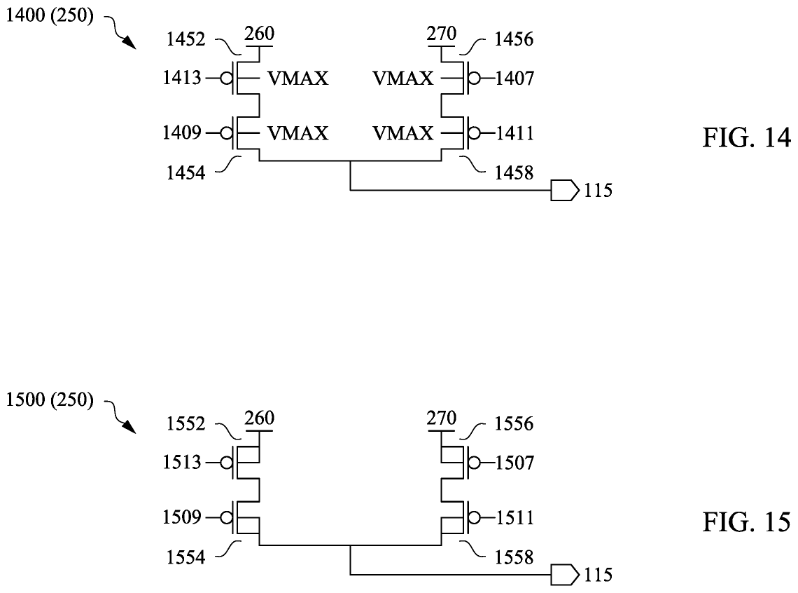

FIG. 14 and FIG. 15 illustrate schematic diagrams of other example implementations 1400 and 1500 of the switch circuit 250 (FIG. 2), respectively, according to some embodiments of the present disclosure. In general, the implementations 1400 and 1500 of the switch circuit 250 are each substantially similar to the implementation discussed with respect to the circuit 300 (FIG. 3), 500 (FIG. 5), 700 (FIG. 7), and 1000 (FIG. 10), except that each header transistor of the implementations 1400 and 1500 has its substrate (or bulk) electrically connected to a voltage supply. By tying the substrate to a voltage supply, potential latch-up issues can be advantageously avoided.

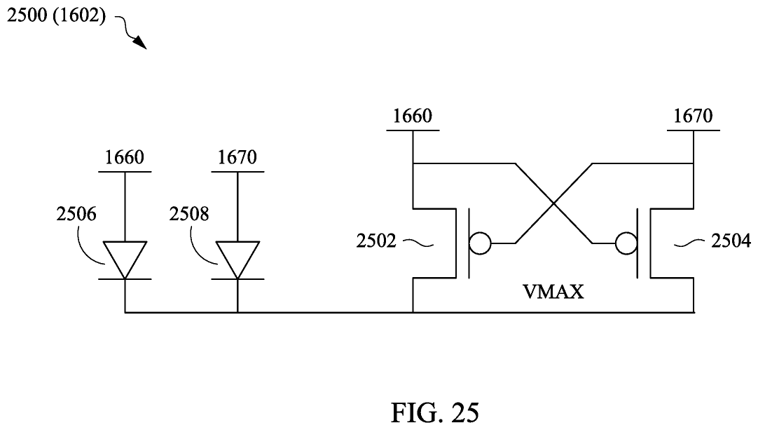

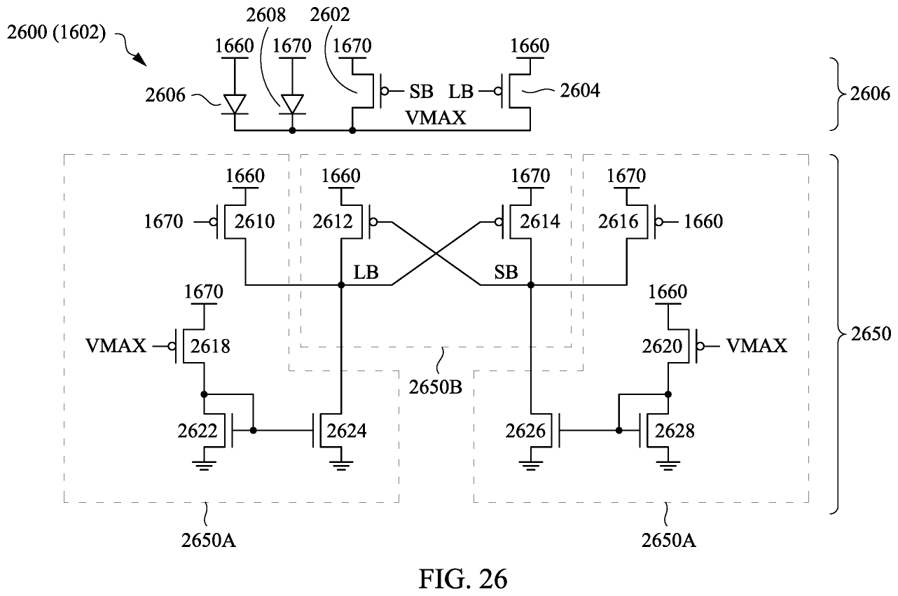

For example in FIG. 14, the implementation 1400 also includes header transistors 1452, 1454, 1456, and 1458, each of which includes a PMOS transistor. Further similarly, the header transistors 1452 and 1454, connected in series, are also coupled between the first voltage supply 260 (V_{DDM}) and the output node (voltage supply 115); and the header transistors 1456 and 1458, connected in series, are also coupled between the second voltage supply 270 (V_{DD}) and the output node (voltage supply 115). In the example of FIG. 14, however, each of the header transistors 1452 to 1458 has its bulk connected to a voltage supply, VMAX. In some embodiments, the voltage supply VMAX may be selected from a greater one of the first voltage supply 260 or the second voltage supply 270. In some embodiments, the voltage supply VMAX can be selected by a maximum voltage selection circuit integrated to/with the voltage supply selection circuit 110, which will be discussed below in FIGS. 25 and 26. By tying the bulk to the greater one of the first or second voltage supply, it can be assured that a bulk voltage of each of the header transistors is higher than or equal to its corresponding source voltage, which can help prevent almost any latch-up issues from being incurred.

For example in FIG. 15, the implementation 1500 also includes header transistors 1552, 1554, 1556, and 1558, each of which includes a PMOS transistor. Further similarly, the header transistors 1552 and 1554, connected in series, are also coupled between the first voltage supply 260 (V_{DDM}) and the output node (voltage supply 115); and the header transistors 1556 and 1558, connected in series, are also coupled between the second voltage supply 270 (V_{DD}) and the output node (voltage supply 115). In the example of FIG. 15, however, the header transistor 1552 has its bulk tied to its source, i.e., connected to the first voltage supply 260; the header transistor 1556 has its bulk tied to its source, i.e., connected to the second voltage supply 270; the header transistor 1554 has its bulk tied to its drain, i.e., connected to the voltage supply 115; and the header transistor 1558 has its bulk tied to its drain, i.e., connected to the voltage supply 115. In this way, the voltage drop from the source to bulk and from the drain to bulk for each of the header transistors (e.g., 1552 and 1554) along the selected conduction path can be assured to be equal to 0 volts, which can prevent any latch-up issues. On the other hand, along the unselected path, the current flowing through the header transistors (e.g., 1556 and 1558) can be fixed at the level of subthreshold leakage or reverse junction current. Thus, latch-up issues can barely occur in the unselected header transistors.

FIG. 16 is an example illustration 1600 of the voltage supply selection circuit 110 (hereinafter “voltage supply selection circuit 1600”), according to some embodiments of the present disclosure. As shown, the voltage supply selection circuit 1600 includes a maximum voltage selection circuit 1602, a switch control (sometimes referred to as a control circuit) 1620, and a voltage supply switch (sometimes referred to as a switch circuit) 1650. The voltage supply selection circuit 1600 receives (or is electrically coupled to) a selection signal 1610 as an input. In some embodiments, the selection signal 1610 can be provided to voltage supply selection circuit 1600 by the circuit 120 (FIG. 1) or by another circuit not shown in the system 100 (FIG. 1). Based on the selection signal 1610, the voltage supply selection circuit 1600 can output either a first voltage supply 1660 or a second voltage supply 1670 at the voltage supply 115.

In some embodiments, the first voltage supply 1660 can be V_{DDM} and second voltage supply 1670 can be V_{DD}. The first voltage supply 1660 (V_{DDM}) may be configured in a first voltage domain (sometimes referred to as V_{DDM} domain), and the second voltage supply 1670 (V_{DD}) may be configured in a second voltage domain (sometimes referred to as V_{DD} domain). Further, the first voltage supply 1660 (within the V_{DDM} domain) may be fixed at a constant voltage level over time, while the second voltage supply 1670 (within the V_{DD} domain) may transition from a lower voltage level to a higher voltage level over time, according to some implementation of the present disclosure.

In brief overview, the maximum voltage selection circuit 1602, which will be discussed below in FIGS. 25 and 26, can provide a voltage supply VMAX by (e.g., dynamically) selecting a greater one of the first voltage supply 260 (V_{DDM}) or the second voltage supply 270 (V_{DD}). The control circuit 1620 can receive (or be electrically coupled to) the selection signal 1610 as an input. The control circuit 1620 can receive the voltage supply VMAX as its power supply voltage. Based on the selection signal 1610, the control circuit 1620 can provide a number of control signals to the switch circuit 1650, which is electrically coupled to both of the first voltage supply 1660 and second voltage supply 1670. The switch circuit 1650 can then output the voltage supply 115 equal to the first voltage supply 1660 or second voltage supply 1670 based on the control signals.

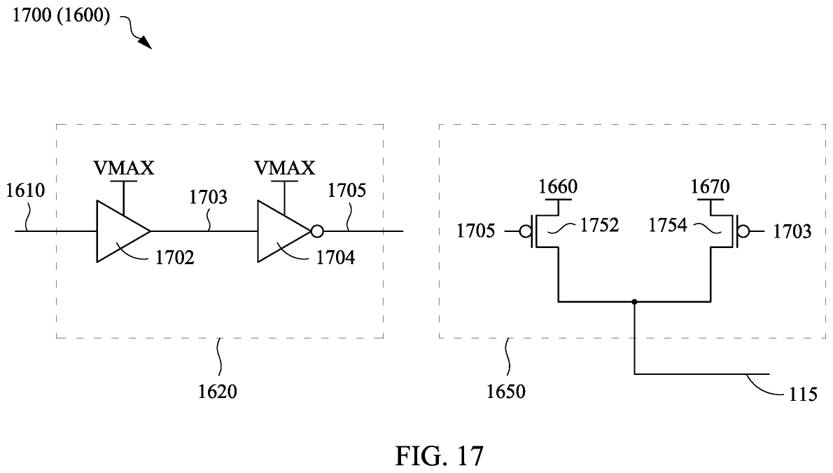

FIG. 17 illustrates a schematic diagram of an example circuit 1700 implemented as the voltage supply selection circuit 1600 shown in FIG. 16. As shown in FIG. 17 (where the maximum voltage selection circuit 1602 is not shown for clarity), the control circuit 1620 includes level shifter 1702 and inverter 1704. The level shifter 1702 and inverter 1704 may operate with the voltage supply VMAX selected by the maximum voltage selection circuit 1602. The switch circuit 1650 includes a number of header transistors 1752 and 1754. Each of the header transistors 1752 and 1754 is implemented as a p-type metal-oxide-semiconductor (PMOS) field-effect-transistor. However, it should be understood that the header transistors 1752 and 1754 can each be implemented as any of various other types of transistors, while remaining within the scope of the present disclosure.

According to various embodiments, with the circuit 1700 shown in FIG. 17, the selection signal 1610 may be configured in the first voltage domain (V_{DDM} domain). As such, the level shifter 1702 (powered by the voltage supply VMAX) can shift the selection signal 1610 from the first voltage domain (V_{DDM} domain) to a voltage domain of the voltage supply (which can be either V_{DD} domain or V_{DDM} domain depending on whether V_{DD} or V_{DDM} is selected), and provide it as a control signal 1703. In some embodiments, the voltage domain of the control signal 1703 may be referred to as VMAX domain. It should be noted that the VMAX domain may vary with the greater one of the V_{DD} or the V_{DDM}, which will be discussed below. The inverter 1704 (powered by the voltage supply VMAX) can logically invert the shifted selection signal (i.e., control signal 1703) and provide it as a control signal 1705 in the VMAX domain.

The control signal 1703 is received by a gate of the header transistor 1754, and the control signal 1705 is received by a gate of the header transistor 1752. The header transistor 1754 is coupled between the second voltage supply 1770 (V_{DD}) and an output node of the voltage supply selection circuit 1600 presenting the voltage supply 115. For example, a source of the header transistor 1754 is connected to the second voltage supply 1770 (V_{DD}) and a drain of the header transistor 1754 is connected to the output node (voltage supply 115). Similarly, the header transistor 1752 is coupled between the first voltage supply 1660 (V_{DDM}) and the output node (voltage supply 115). The control signal 1705, that is logically inverted to the control signal 1703, is received by a gate of the header transistor 1752.

In some embodiments, the header transistor 1754 may form a second conduction path configured to selectively couple the second voltage supply 1670 (V_{DD}) to the voltage supply 115, and the header transistor 1752 may form a first conduction path configured to selectively couple the first voltage supply 1660 (V_{DDM}) to the voltage supply 115. The first and second conduction paths may be complementarily conducted or otherwise selected based on the control signals 1703 and 1705, in which the control signals 1703 and 1705 are logically inverted to each other. For example when the selection signal 1610 is at logic high, the control signals 1703 and 1705, in the same voltage domain, can be pulled to logic high and logic low, respectively. As such, the header transistor 1754 is turned off, while the header transistor 1752 is turned on. As such, the first conduction path is conducted so as to output the voltage supply 115 as the first voltage supply 1660 (V_{DDM}), while the second conduction path can be almost entirely shut off. Table II below shows a summary of logic states of the selection signal 1610, control signals 1703 and 1705, and the voltage supply 115.

TABLE II

| 1610 | 1705 | 1703 | 115 |
|---|---|---|---|
| 0 | 1 | 0 | V_{DD} |
| 1 | 0 | 1 | V_{DDM} |

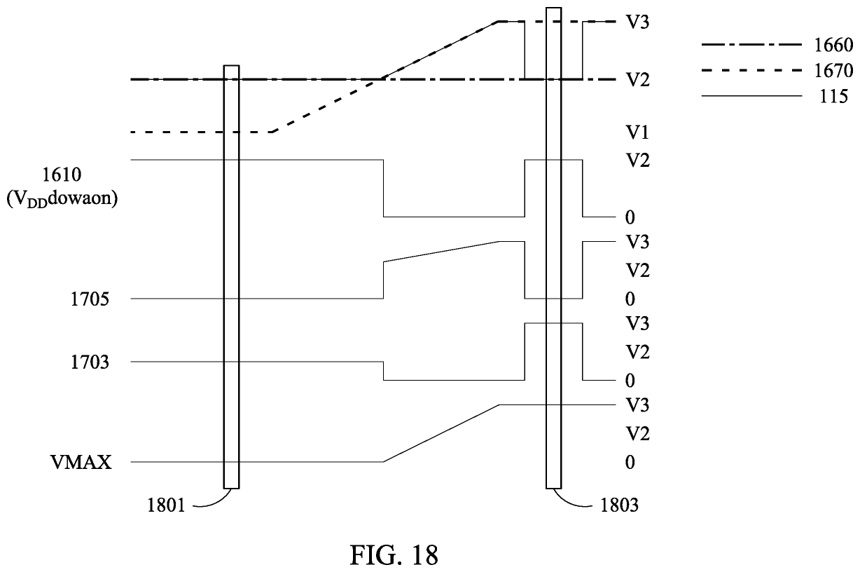

FIG. 18 illustrates analog waveforms of the selection signal 1610, the control signals 1703 and 1705, the voltage supplies 1660-1670, the voltage supply VMAX, and the voltage supply 115 presented by the circuit 1700 of FIG. 17 over time, according to some embodiments of the present disclosure. The selection signal 1610 is configured in the first voltage domain (V_{DDM}) for the example circuit 1700 shown in FIG. 17. For example, the selection signal 1610 may transition between voltage levels: 0 volts and V2 volts, which correspond to logic low and logic high in the V_{DDM} domain, respectively. In some implementation, the first voltage supply 1660 may be fixed at V2 volts, with the second voltage supply 1670 varying from V1 volts to the V3 volts, in which V1 is less than V2 and V2 is less than V3. As such, the voltage supply VMAX (the larger one of the first voltage supply 1660 or second voltage supply 1670) may transition from V2 volts to V3 volts. And, the control signals 1703 and 1705 may transition between voltage levels: 0 volts and V3 volts, which correspond to logic low and logic high in the VMAX domain, respectively.

During an example time period 1801 indicated in FIG. 18, the selection signal 1610 is provided at logic high (i.e., V2 volts). Upon receiving the selection signal 1610, the level shifter 1702 can shift it to the VMAX domain as the control signal 1703. In the time period 1801, the first voltage supply 1660 (V2 volts) is greater than the second voltage supply 1670 (V1 volts), and thus, VMAX is selected as V2 volts. Accordingly, the VMAX domain ranges from 0 volts to V2 volts in the time period 1801. By logically inverting the control signal 1703, the inverter 1704 can output the control signal 1705 at logic low in the VMAX domain, i.e., 0 volts. As a result, the header transistors 1752 and 1754, respectively gated by the control signals 1705 and 1703, can be turned on and off, respectively. The first supply voltage 1660 (fixed at V2 volts) is thus coupled to the voltage supply 115. In addition, the header transistor 1754 can be entirely shut off in such a case (the first voltage supply 1660>the second voltage supply 1670), with its voltage drop across the source and gate being less than 0 volts. For example, the source and gate of the header transistor 1754 are equal to V1 volts and V2 volts, respectively.

During another example time period 1803 indicated in FIG. 18, similarly, the header transistors 1752 and 1754, respectively gated by the control signals 1705 and 1703, can be turned on and off, respectively. However, in such a case, the first voltage supply 1660 is instead lower than the second voltage supply 1670. Even so, the header transistor 1754 can still be entirely shut off, with its voltage drop across the source and gate being equal to 0 volts. For example, the source and gate of the header transistor 1754 are both equal to V3 volts.

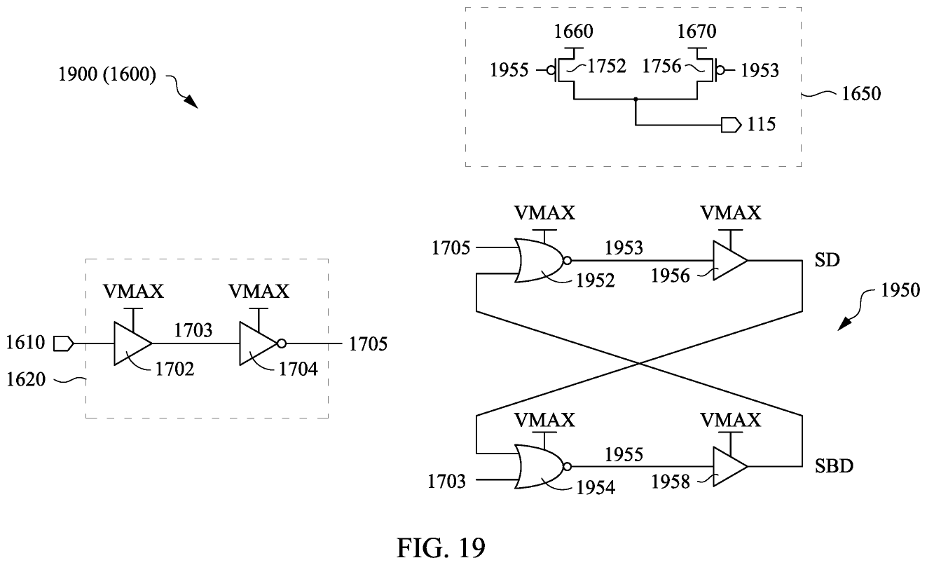

FIG. 19 illustrates a schematic diagram of another example circuit 1900 implemented as the voltage supply selection circuit 1600 shown in FIG. 16, without the maximum voltage selection circuit 1602 being shown. The circuit 1900 and circuit 1700 (FIG. 17) have their respective control circuits 1620 and switch circuits 1650 configured by the same circuit-level representations. The circuit 1900 further includes a timing control circuit 1950 configured to assure that the header transistors 1752 and 1754 can remain on during switching between the first voltage supply 1660 (V_{DDM}) and the second voltage supply 1670 (V_{DD}).

Different from the circuit 1700, the control signals 1703 and 1705 provided by the control circuit 1620 are further processed by the timing control circuit 1950 to provide control signals 1953 and 1955 gating the header transistors 1754 and 1752 of the switch circuit 1650, respectively. Such control signals 1953 and 1955 can remain at logic low during the switching between the first voltage supply 1660 (V_{DDM}) and the second voltage supply 1670 (V_{DD}), i.e., transition of the selection signal 1610. As such, the header transistors 1754 and 1752 can remain on during the switching, which can advantageously prevent the voltage supply 115 from floating during the transition of the selection signal 1610.

The timing control circuit 1950 includes NOR gates 1952 and 1954, and delay circuits 1956 and 1958. In some embodiments, the delay circuits 1956 and 1958 can each include a respective number of inverters serially connected to one another. The NOR gates 1952-1954, and delay circuits 1956-1958 may operate with the voltage supply VMAX. Further, the NOR gates 1952 and 1954 form a NOR-type SR latch operating with the voltage supply VMAX and having its outputs coupled to the delayed circuits 1956-1958. For example in FIG. 19, the NOR gate 1952 receives the control signal 1705 and delayed signal SBD as inputs to provide control signal 1953; and the NOR gate 1954 receives the control signal 1703 and delayed signal SD as inputs to provide control signal 1955. By combining the NOR-type SR latch with the delayed circuits, the control signals 1953 and 1955, which gate the header transistors 1754 and 1752, respectively, can be held at logic low during the switching between the first voltage supply 1660 and second voltage supply 1670.

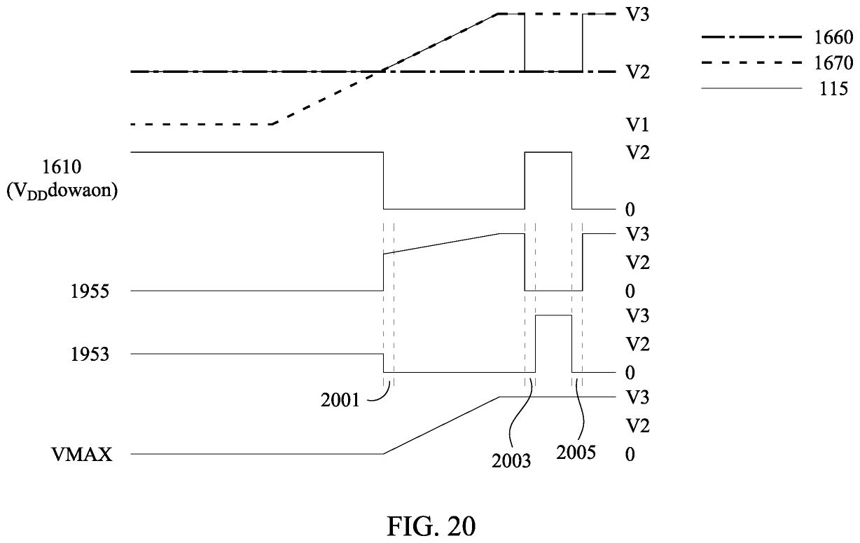

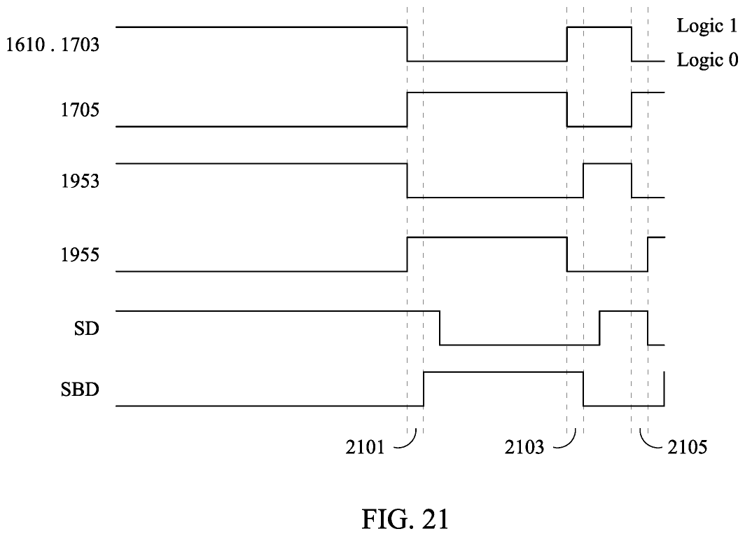

FIG. 20 and FIG. 21 illustrate analog waveforms and logic waveforms presented by the circuit 1900 of FIG. 19 over time, respectively. For example, FIG. 20 illustrates analog waveforms of the selection signal 1610, the first and second voltage supplies 1660-1670, the voltage supply 115, the voltage supply VMAX, and the control signals 1953-1955, respectively; and FIG. 21 illustrates logic waveforms of the selection signal 1610, control signals 1703-1705 and 1953-1955, and delayed signals SD and SBD, respectively. As shown in FIG. 20, during the transition of selection signal 1610, e.g., time periods 2001, 2003, and 2005, each of the control signals 1953 and 1955 are held at logic low. Thus, the header transistors 1752 and 1754 can remain on during such periods, thereby preventing the voltage supply 115 from floating. Time periods 2101, 2103, and 2105, as indicted in FIG. 21, can correspond to the time periods 2001, 2003, and 2005, respectively, during which the control signals 1953 and 1955 remain at logic low.

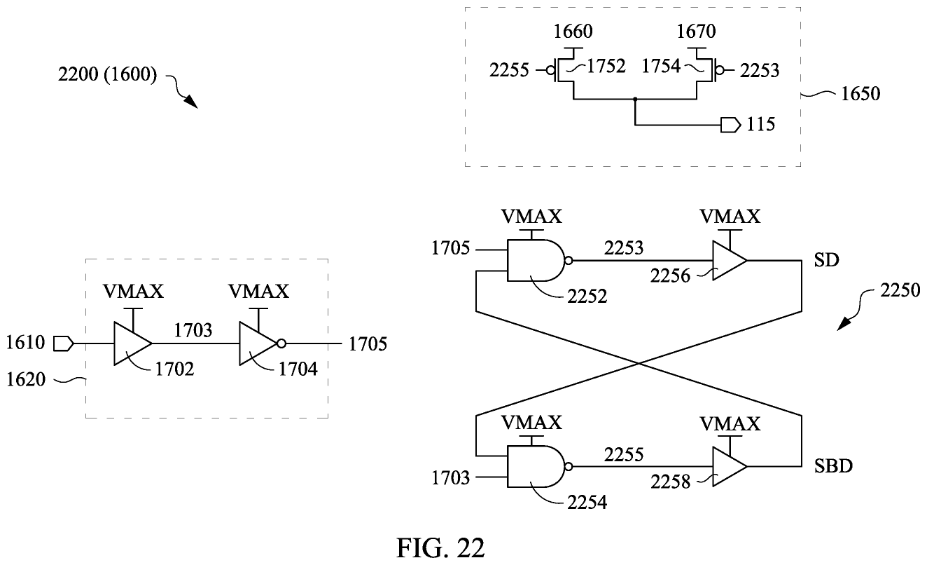

FIG. 22 illustrates a schematic diagram of another example circuit 2200 implemented as the voltage supply selection circuit 1600 shown in FIG. 16, without the maximum voltage selection circuit 1602 being shown. The circuit 2200 and circuit 1700 (FIG. 17) have their respective control circuits 1620 and switch circuits 1650 configured by the same circuit-level representations. The circuit 2200 further includes a timing control circuit 2250 configured to assure that the header transistors 1752 and 1754 can remain on during switching between the first voltage supply 1660 (V_{DDM}) and the second voltage supply 1670 (V_{DD}).

Different from the circuit 1700, the control signals 1703 and 1705 provided by the control circuit 1620 are further processed by the timing control circuit 2250 to provide control signals 2253 and 2255 gating the header transistors 1754 and 1752 of the switch circuit 1650, respectively. Such control signals 2253 and 2255 can remain at logic high during the switching between the first voltage supply 1660 (V_{DDM}) and the second voltage supply 1670 (V_{DD}), i.e., transition of the selection signal 1610. As such, the header transistors 1754 and 1752 can remain off during the switching, which can advantageously prevent the voltage supply 115 from floating during the transition of the selection signal 1610.

The timing control circuit 2250 includes NAND gates 2252 and 2254, and delay circuits 2256 and 2258. In some embodiments, the delay circuits 2256 and 2258 can each include a respective number of inverters serially connected to one another. The NAND gates 2252-2254, and delay circuits 2256-2258 may operate with the voltage supply VMAX. Further, the NAND gates 2252 and 2254 form a NAND-type SR latch operating with the voltage supply VMAX and having its outputs coupled to the delayed circuits 2256-2258. For example in FIG. 22, the NAND gate 2252 receives the control signal 1705 and delayed signal SBD as inputs to provide control signal 2253; and the NAND gate 2254 receives the control signal 1703 and delayed signal SD as inputs to provide control signal 2255. By combining the NAND-type SR latch with the delayed circuits, the control signals 2253 and 2255, which gate the header transistors 1754 and 1752, respectively, can be held at logic HIGH during the switching between the first voltage supply 1660 and second voltage supply 1670.

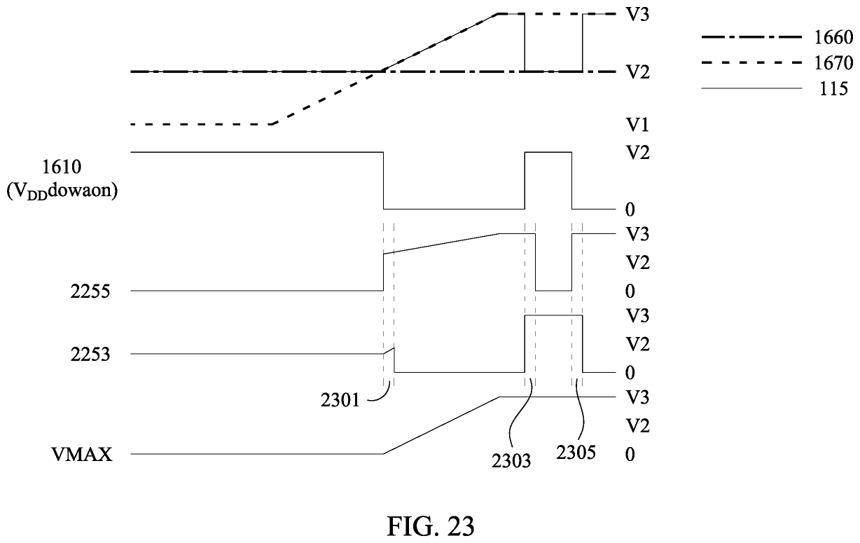

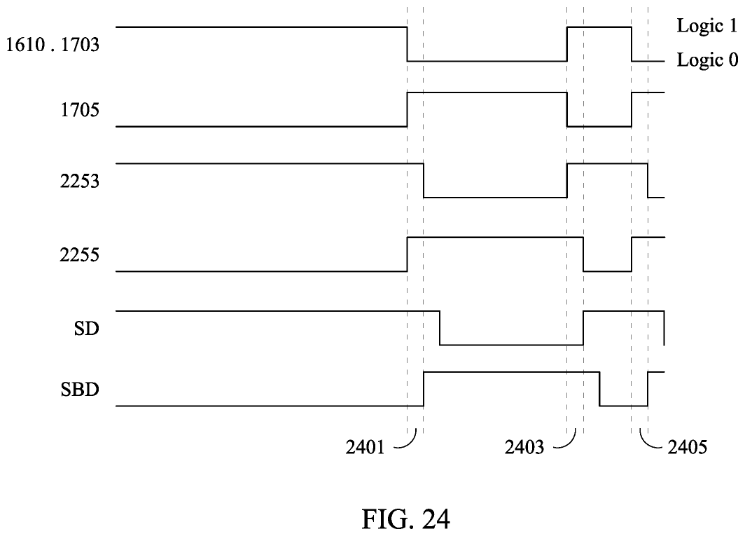

FIG. 23 and FIG. 24 illustrate analog waveforms and logic waveforms presented by the circuit 2200 of FIG. 22 over time, respectively. For example, FIG. 23 illustrates analog waveforms of the selection signal 1610, the first and second voltage supplies 1660-1670, the voltage supply 115, the voltage supply VMAX, and the control signals 2253-2255, respectively; and FIG. 24 illustrates logic waveforms of the selection signal 1610, control signals 1703-1705 and 2253-2255, and delayed signals SD and SBD, respectively. As shown in FIG. 23, during the transition of selection signal 1610, e.g., time periods 2301, 2303, and 2305, each of the control signals 2253 and 2255 are held at logic high. Thus, the header transistors 1752 and 1754 can remain off during such periods, thereby preventing the voltage supply 115 from floating. Time periods 2401, 2403, and 2405, as indicted in FIG. 24, can correspond to the time periods 2301, 2303, and 2305, respectively, during which the control signals 2253 and 2255 remain at logic high.

FIG. 25 and FIG. 26 illustrate schematic diagrams of example circuits 2500 and 2600 implemented as the maximum voltage selection circuit 1602 (FIG. 16), respectively, according to some embodiments of the present disclosure. As mentioned above, the maximum voltage selection circuit 1602 can select a greater one of a first voltage supply (e.g., V_{DDM}) or a second voltage supply (e.g., V_{DD}), and provide the selected one as a voltage supply (e.g., VMAX) for at least one of the embodiments of the voltage supply selection circuit, as herein disclosed.

In various embodiments, the maximum voltage selection circuit 1602 can dynamically detect (e.g., compare) whether the VMAX, output by the maximum voltage selection circuit 1602, is lower than either the V_{DD} or V_{DDM}. For example, the VMAX has been equal to, or substantially close to, the V_{DD} and higher than the V_{DDM}, but becomes lower than V_{DDM} (e.g., because the V_{DDM} is increasing), or the VMAX has been equal to, or substantially close to, the V_{DDM} and higher than the V_{DD}, but now becomes lower than V_{DD} (e.g., because the V_{DD} is increasing). If so (e.g., any of the above cases occur), the maximum voltage selection circuit 1602 can cause a latch circuit to change (e.g., flip) output(s) of the latch circuit. In response, the maximum voltage selection circuit 1602 can re-select the currently higher one between the V_{DD} and V_{DDM} as the VMAX.

For example in FIG. 25, the circuit 2500 includes PMOS transistors 2502-2504 and diodes 2506-2508. The transistors 2502 and 2504 are cross-coupled to each other, i.e., a gate of one of the transistors 2502 and 2504 being connected to a source of the other of the transistors 2502 and 2504. Further, the source of the transistor 2502 is connected to the first voltage supply 1660 (V_{DDM}) and the source of the transistor 2504 is connected to the second voltage supply 1670 (V_{DD}), with their respective drains connected to an output node of the circuit 2500 (i.e., an output node of the maximum voltage selection circuit 1602 presenting the voltage supply VMAX). In some embodiments, the cross-coupled transistors 2502 and 2504 can function as the latch circuit, as described above, where output(s) of the latch circuit present the voltage supply VMAX.

The diode 2506 is coupled to the first voltage supply 1660 and the voltage supply VMAX at its respective anode and cathode; and similarly, the diode 2508 is coupled to the second voltage supply 1670 and the voltage supply VMAX at its respective anode and cathode. The diodes 2506's and 2508's cathodes are both coupled to the output node that presents the selected voltage supply VMAX. In some embodiments, the diode 2506 can function as a fuse to assure that the voltage supply VMAX does not drop below a threshold voltage that can be defined by the first voltage supply 1660 (V_{DD}) minus a forward voltage of the diode 2506 (e.g., volts); and similarly, the diode 2508 can function as a fuse to make sure that the voltage supply VMAX does not drop below a threshold voltage that can be defined by the second voltage supply 1670 (V_{DDM}) minus a forward voltage of the diode 2508 (e.g., 0.7 volts).

For example in FIG. 26, the circuit 2600 includes PMOS transistors 2602-2604 and diodes 2606-2608, which are substantially similar to the transistors 2502-2504 and diodes 2506-2508, respectively, except that the transistors 2606-2608 are not cross-coupled to each other. Instead, the transistors 2606 and 2608 are gated by control signals SB and LB, respectively. Accordingly, their following discussion will be focused on the difference. For example, the circuit 2600 further includes PMOS transistors 2610, 2612, 2614, 2616, 2618, and 2620, and NMOS transistors 2622, 2624, 2626, and 2628.

In some embodiments, the circuit 2600 can operatively include a comparator circuit 2650 (formed by the PMOS transistors 2610-2620 and NMOS transistors 2622-2628) and a selection circuit 2660 (formed by the PMOS transistors 2602-2604 and diodes 2606-2608). Further, the comparator 2650 includes power detection circuits 2650A and a latch circuit 2650B, as indicted in the example of FIG. 26. The comparator circuit 2650 can use the power detection circuit 2650A to dynamically detect (e.g., compare) whether the voltage supply VMAX, output by the circuit 2600, is lower than either the second voltage supply 1670 (V_{DD}) or the first voltage supply 1660 (V_{DDM}). If so, the power detection circuit 2650A may cause the latch circuit 2650B to change (e.g., flip) the control signals, LB and SB, output by comparator circuit 2650B. In response to the change of the output signals, the selection circuit 2660 can re-select the currently higher one between the second voltage supply 1670 (V_{DD}) and the first voltage supply 1660 (V_{DDM}) as the voltage supply VMAX.

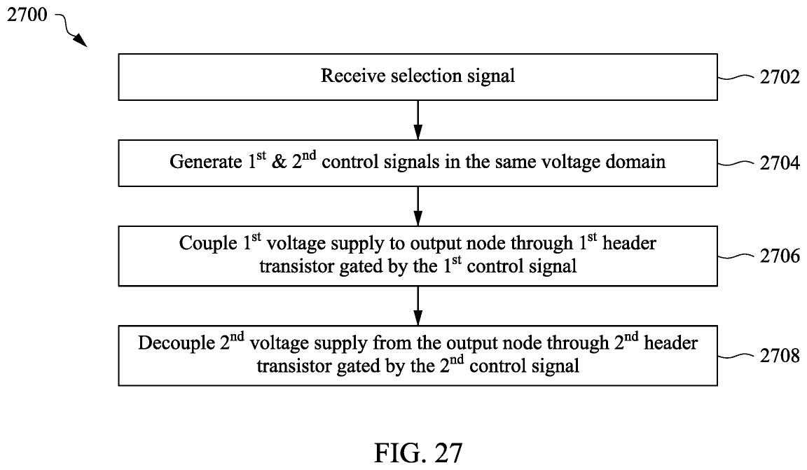

FIG. 27 illustrates a flowchart of an example method 2700 of operating a voltage supply selection circuit, in accordance with some embodiments. The method 2700 may be used to operate the voltage supply selection circuit 110. For example, at least some of the operations described in the method 2700 can complementarily couple one of two voltage supplies to an output node of the voltage supply selection circuit 110 based on a selection signal. It is noted that the method 2700 is merely an example and is not intended to limit the present disclosure. Accordingly, it is understood that additional operations may be provided before, during, and after the method 2700 of FIG. 27, and that some other operations may only be briefly described herein.

The method 2700 starts with operation 2702 in which a selection signal is provided as the input to a voltage supply selection circuit, in accordance with various embodiments. For example in FIG. 3, the selection signal 210 can be input to the control circuit 220 of the voltage supply selection circuit 200. The voltage supply selection circuit 200 can provide a voltage supply (e.g., 115) to an operatively coupled circuit (e.g., 120) by coupling one of a first voltage supply (e.g., 260, V_{DDM}) or a second voltage supply (e.g., 270, V_{DD}) to an output node of the voltage supply selection circuit 200. For another example in FIG. 17, the selection signal 1610 can be input to the control circuit 1620 of the voltage supply selection circuit 1600. The voltage supply selection circuit 1600 can provide a voltage supply (e.g., 115) to an operatively coupled circuit (e.g., 120) by coupling one of a first voltage supply (e.g., 1660, V_{DDM}) or a second voltage supply (e.g., 1670, V_{DD}) to an output node of the voltage supply selection circuit 1600. In some embodiments, to simplify design of the corresponding voltage supply selection circuit, the first voltage supply (V_{DDM}) may be configured as at a fixed voltage level, with only the second voltage supply (V_{DD}) varying over time.

The method 2700 continues to operation 2704 in which at least a first control signal and a second control signal, that are configured in the same voltage domain, are generated based on the selection signal, in accordance with various embodiments. Continuing with the above example in FIG. 3, the first control signal (e.g., 307/311) and the second control signal (e.g., 309/313) are generated based on the selection signal 210. Further, the first and second control signals, 307 and 309 (or 311 and 313), are in the same voltage domain and are logically inverse to each other. Similarly in the example of FIG. 17, the first control signal (e.g., 1703) and the second control signal (e.g., 1705) are generated based on the selection signal 1610. Further, the first and second control signals, 1703 and 1705, are in the same voltage domain and are logically inverse to each other.

The method 2700 continues to operation 2706 in which the first voltage supply is coupled to the output node through a first header transistor gated by the first control signal, in accordance with various embodiments. Continuing with the above example in FIG. 3, the first control signals 307 and 311, respectively gating the header transistors 356 and 358, can turn them on, thereby coupling the second voltage supply 270 (V_{DD}) to the output node. In the example of FIG. 17, the first control signal 1703, gating the header transistor 1754, can turn it on, thereby coupling the second voltage supply 1670 (V_{DD}) to the output node.

The method 2700 continues to operation 2708 in which the second voltage supply is coupled to the output node through a second header transistor gated by the second control signal, in accordance with various embodiments. For example in FIG. 3, the second control signals 313 and 309, respectively gating the header transistors 352 and 354, can turn them off, thereby decoupling the first voltage supply 260 (V_{DDM}) from the output node. In the example of FIG. 17, the second control signal 1705, gating the header transistor 1752, can turn it off, thereby decoupling the first voltage supply 1660 (V_{DDM}) from the output node. Operations 2706 and 2708 can be concurrently performed, in some embodiments. As such, only one of the first or second voltage supply can be coupled to the output node. Further, in various embodiments of the present disclosure, as the first and second control signals are configured in the same voltage domain, any potential leakage that could be induced along the unselected conduction path (i.e., the path through the turned-off header transistor(s)) can be significantly reduced.

In one aspect of the present disclosure, a circuit is disclosed. The circuit includes a control circuit configured to receive a selection signal transitioning within a first voltage domain; and generate, based on the selection signal, a first control signal transitioning within a second voltage domain different from the first voltage domain. The circuit further includes a switch circuit operatively coupled to the control circuit and comprising a first header transistor coupled to a first voltage supply transitioning within the second voltage domain, and gated by the first control signal; and a second header transistor coupled to a second voltage supply transitioning within the first voltage domain, and gated by a second control signal that is logically inverse to the first control signal. The first header transistor and the second header transistor are complementarily turned on so as to provide an output voltage equal to either the first voltage supply or the second voltage supply.

In another aspect of the present disclosure, a circuit is disclosed. The circuit includes a control circuit configured to receive a selection signal transitioning within a first voltage domain; and generate, based on the selection signal, a first control signal and a second control signal transitioning within a second voltage domain different than the first voltage domain. The first control signal and the second control single are logically inverse to each other. The circuit further includes a switch circuit operatively coupled to the control circuit and comprising a first header transistor coupled to a first voltage supply transitioning within the second voltage domain, and gated by the first control signal; and a second header transistor coupled to a second voltage supply transitioning within the first voltage domain, and gated by the second control signal. The first header transistor and the second header transistor are complementarily turned on so as to couple either the first voltage supply or the second voltage supply to an output node.

In yet another aspect of the present disclosure, a method for selecting a voltage supply is disclosed. The method includes receiving a selection signal transitioning in a first voltage domain. The method includes generating, based on the selection signal, a first control signal and a second control signal that are logically inverse to each other and transition within a second voltage domain different from the first voltage domain. The method includes coupling a first voltage supply to an output node through a first header transistor that is gated by the second control signal, wherein the first voltage supply transitions within the first voltage domain. The method includes decoupling a second voltage supply from the output node through a second header transistor that is gated by the first control signal, wherein the second voltage supply transitions within the second voltage domain.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a control circuit configured to:
receive a selection signal transitioning within a first voltage domain; and
generate, based on the selection signal, a first control signal transitioning within a second voltage domain different from the first voltage domain; and
a switch circuit operatively coupled to the control circuit and comprising:
a first header transistor coupled to a first voltage supply transitioning within the second voltage domain, and gated by the first control signal; and
a second header transistor coupled to a second voltage supply transitioning within the first voltage domain, and gated by a second control signal that is logically inverse to the first control signal;
wherein the first header transistor and the second header transistor are complementarily turned on so as to provide an output voltage equal to either the first voltage supply or the second voltage supply.

2. The circuit of claim 1, wherein the control circuit comprises a level shifter powered by the first voltage supply, and configured to receive the selection signal and shift the selection signal from the first voltage domain to the second voltage domain.

3. The circuit of claim 2, wherein the switch circuit comprises:
a third header transistor coupled to the first header transistor in series, wherein the third header transistor is gated by a third control signal transitioning within the first voltage domain; and
a fourth header transistor coupled to the second header transistor in series, wherein the fourth header transistor is gated by a fourth control signal that is logically inverse to the third control signal.

4. The circuit of claim 3, wherein the first and second control signals are generated based on the shifted selection signal.

5. The circuit of claim 3, wherein each of the first to fourth header transistors includes a p-type metal-oxide-semiconductor (PMOS) transistor.

6. The circuit of claim 5, wherein the second and fourth header transistors each have its V_{SG} equal to or less than 0 volts (V) when providing the output voltage equal to the first voltage supply, and the first and third header transistors each have its V_{SG} equal to or less than 0 V when providing the output voltage equal to the second voltage supply.

7. The circuit of claim 3, further comprising:
a first NOR-type SR latch;
one or more first delay circuits coupled to the first NOR-type SR latch;
a second NOR-type SR latch; and
one or more second delay circuits coupled to the second NOR-type SR latch;
wherein, during transition between the first voltage supply and the second voltage supply, the first to fourth header transistors are each configured to be turned on through the first NOR-type SR latch, the one or more first delay circuits, the second NOR-type SR latch, and the one or more second delay circuits.

8. The circuit of claim 3, further comprising:
a first NAND-type SR latch;
one or more first delay circuits coupled to the first NAND-type SR latch;
a second NAND-type SR latch; and
one or more second delay circuits coupled to the second NAND-type SR latch;
wherein, during transition between the first voltage supply and the second voltage supply, the first to fourth header transistors are each configured to be turned off through the first NAND-type SR latch, the one or more first delay circuits, the second NAND-type SR latch, and the one or more second delay circuits.

9. The circuit of claim 1, further comprising:
a maximum voltage selection circuit configured to select a greater one of the first voltage supply or second voltage supply;
wherein the control circuit comprises a level shifter powered by the greater one of the first voltage supply or second voltage supply, and configured to receive the selection signal and shift the selection signal from the first voltage domain to the second voltage domain.

10. The circuit of claim 9, wherein the first and second control signals are generated based on the shifted selection signal.

11. The circuit of claim 9, further comprising:
a NOR-type SR latch;
one or more delay circuits coupled to the NOR-type SR latch;
wherein, during transition between the first voltage supply and the second voltage supply, the first to second header transistors are each configured to be turned on through the NOR-type SR latch and the one or more delay circuits.

12. The circuit of claim 9, further comprising:
a NAND-type SR latch;
one or more delay circuits coupled to the NAND-type SR latch;
wherein, during transition between the first voltage supply and the second voltage supply, the first to second header transistors are each configured to be turned off through the NAND-type SR latch and the one or more delay circuits.

13. A circuit, comprising:
a control circuit configured to:
receive a selection signal transitioning within a first voltage domain; and
generate, based on the selection signal, a first control signal and a second control signal transitioning within a second voltage domain different than the first voltage domain, wherein the first control signal and the second control single are logically inverse to each other; and
a switch circuit operatively coupled to the control circuit and comprising:
a first header transistor coupled to a first voltage supply transitioning within the second voltage domain, and gated by the first control signal; and
a second header transistor coupled to a second voltage supply transitioning within the first voltage domain, and gated by the second control signal;
wherein the first header transistor and the second header transistor are complementarily turned on so as to couple either the first voltage supply or the second voltage supply to an output node.

14. The circuit of claim 13, wherein the switch circuit further comprises:
a third header transistor coupled to the first header transistor in series, wherein the third header transistor is gated by a third control signal transitioning in the first voltage domain; and
a fourth header transistor coupled to the second header transistor in series, wherein the fourth header transistor is gated by a fourth control signal logically inverse to the third control signal.

15. The circuit of claim 14, wherein each of the first to fourth header transistors is a p-type metal-oxide-semiconductor (PMOS) transistor, and wherein the output node is directly connected to a drain of the second header transistor and a drain of the third header transistor.

16. The circuit of claim 14, wherein the control circuit comprises:
an even number of first inverters configured to receive the selection signal in the first voltage domain and generate the first and second control signals;
a level shifter configured to shift the selection signal to the second voltage domain; and
an even number of second inverters configured to receive the shifted selection signal and generate the third and fourth control signals.

17. The circuit of claim 13, wherein each of the first and second header transistors is a p-type metal-oxide-semiconductor (PMOS) transistor, and wherein the output node is directly connected to a drain of the first header transistor and a drain of the second header transistor.

18. The circuit of claim 17, wherein the control circuit comprises:
a level shifter configured to shift the selection signal transitioning in the first voltage domain to the second voltage domain and output the shifted selection signal as the first control signal; and
an odd number of inverters configured to invert the shifted selection signal as the second control signal.

19. A method for selecting a voltage supply, comprising:
receiving a selection signal transitioning in a first voltage domain;
generating, based on the selection signal, a first control signal and a second control signal that are logically inverse to each other and transition within a second voltage domain different from the first voltage domain;
coupling a first voltage supply to an output node through a first header transistor that is gated by the second control signal, wherein the first voltage supply transitions within the first voltage domain; and
decoupling a second voltage supply from the output node through a second header transistor that is gated by the first control signal, wherein the second voltage supply transitions within the second voltage domain.

20. The method of claim 19, wherein each of the first and second header transistors is a p-type metal-oxide-semiconductor (PMOS) transistor, and wherein the output node is directly connected to one of: a drain of the first header transistor or a drain of the second header transistor.
